(19) United States
(12) Patent Application Publication
(10) Pub. No.: US 2026/0353754 A1
(43) Pub. Date: Nov. 5, 2026

(54) SEMICONDUCTOR DEVICE

(71) Applicant: SONY SEMICONDUCTOR SOLUTIONS CORPORATION, Kanagawa (JP)

(72) Inventor: Koichi MATSUMOTO, Kanagawa (JP)

(73) Assignee: SONY SEMICONDUCTOR SOLUTIONS CORPORATION, Kanagawa (JP)

(21) Appl. No.: 19/105,096

(22) PCT Filed: Jul. 10, 2023
(86) PCT No.: PCT/JP2023/025489

§ 371 Date: Feb. 20, 2025

(30) Foreign Application Priority Data
Aug. 31, 2022 (JP) 2022-138514

(51) Int. Cl. H10D 64/27; H10D 30/62

(52) U.S. Cl. CPC H10D 64/514; H10D 30/62

(57) ABSTRACT

The present technology is intended to increase the degree of integration of a semiconductor device. The semiconductor device includes a three-dimensional material layer, a first transistor including the three-dimensional material layer, a two-dimensional material layer, and a second transistor including the two-dimensional material layer. Then, the first transistor and the second transistor are provided on the same substrate.

### TECHNICAL FIELD

The present technology (the technology according to the present disclosure) relates to a semiconductor device and an electronic apparatus, and more particularly to a technology effective when applied to a semiconductor device including a plurality of types of field-effect transistors having gate insulating films of different thicknesses.

### BACKGROUND ART

As field-effect transistors mounted on a semiconductor device, there is known a fin field-effect transistor (Fin-FET) in which a semiconductor layer is processed to form an island-shaped element formation portion (fin portion) protruding from a base, and a gate electrode is provided over three surfaces (an upper surface and two side surfaces) of the island-shaped element formation portion. Furthermore, there is also known a gate all around (GAA)-structure field-effect transistor (GAA-FET) in which a semiconductor layer is processed to form a three-dimensional element formation portion on a base film, and a gate electrode is provided over four surfaces (an upper surface, a bottom surface, and two side surfaces) of the element formation portion. Patent Document 1 discloses fin and GAA-structure field-effect transistors. Patent Document 2, on the other hand, discloses a technology using a two-dimensional material layer as a channel formation portion of a field-effect transistor.

### CITATION LIST

### Patent Document

Patent Document 1: WO 2020/262643 A

Patent Document 2: Japanese Patent Application Laid-Open No. 2021-068719

### SUMMARY OF THE INVENTION

### Problems to be Solved by the Invention

Meanwhile, further high integration is desired in semiconductor devices. To achieve higher integration, the miniaturization of transistors is essential.

The fin and GAA-structure field-effect transistors described above can improve short-channel effects and achieve a necessary operation with a shorter gate length, so that it is possible to achieve the miniaturization of planar size (reduction of occupied area), making the fin and GAA-structure field-effect transistors advantageous in achieving higher integration.

The fin type and the GAA structure, however, tend to cause a plurality of surfaces (the upper surface, the bottom surface, and the two side surfaces) of the element formation portion to generate an electric field, and the electric field in the channel formation portion tends to be stronger. It is therefore difficult to apply the fin type or the GAA structure to a high-withstand voltage field-effect transistor with high operating voltage, that is, a field-effect transistor with a thick gate insulating film.

In a semiconductor device in which circuits having different functions such as a digital circuit and an analog circuit are mounted together, a plurality of types of field-effect transistors with different withstand voltages (film thicknesses of gate insulating films) are used. Therefore, to mount a plurality of types of field-effect transistors with different withstand voltages, further innovation is necessary to achieve higher integration.

Therefore, the present engineer has focused on a two-dimensional material layer and come up with the present technology.

It is therefore an object of the present technology to provide a technology to achieve higher integration.

### Solutions to Problems

(1) A semiconductor device according to an aspect of the present technology includes:
a three-dimensional material layer;
a first transistor including the three-dimensional material layer;
a two-dimensional material layer; and
a second transistor including the two-dimensional material layer.

Then, the first transistor and the second transistor are provided on the same substrate.
(2) A semiconductor device according to another aspect of the present technology, in which
the first transistor includes a field-effect transistor including a gate electrode provided adjacent to the three-dimensional material layer with a gate insulating film interposed therebetween, and
the second transistor includes a field-effect transistor including a gate electrode provided adjacent to the two-dimensional material layer with a gate insulating film interposed therebetween.

Then, the gate insulating film of the second transistor is thicker than the gate insulating film of the first transistor.

### BRIEF DESCRIPTION OF DRAWINGS

FIG. 1 is a plan view schematically illustrating planar patterns of a first field-effect transistor and a second field high transistor mounted on a semiconductor device according to a first embodiment of the present technology.

FIG. 2 is a longitudinal cross-sectional view schematically illustrating a longitudinal cross-sectional structure taken along line a1-a1 in FIG. 1.

FIG. 3 is a longitudinal cross-sectional view schematically illustrating a longitudinal cross-sectional structure taken along line b1-b1 in FIG. 1.

FIG. 4 is a longitudinal cross-sectional view schematically illustrating a longitudinal cross-sectional structure taken along line c1-c1 in FIG. 1.

FIG. 5A is a longitudinal cross-sectional view schematically illustrating a step of a method for manufacturing the semiconductor device according to the first embodiment of the present technology.

FIG. 5B is a longitudinal cross-sectional view schematically illustrating a step subsequent to FIG. 5A.

FIG. 5C is a longitudinal cross-sectional view schematically illustrating a step subsequent to FIG. 5B.

FIG. 5D is a longitudinal cross-sectional view schematically illustrating a step subsequent to FIG. 5C.

FIG. 5E is a longitudinal cross-sectional view schematically illustrating a step subsequent to FIG. 5D.

FIG. 5F is a longitudinal cross-sectional view schematically illustrating a step subsequent to FIG. 5E.

FIG. 5G is a longitudinal cross-sectional view schematically illustrating a step subsequent to FIG. 5F.

FIG. 5H is a longitudinal cross-sectional view schematically illustrating a step subsequent to FIG. 5G.

FIG. 5I is a longitudinal cross-sectional view schematically illustrating a step subsequent to FIG. 5H.

FIG. 6A is a diagram showing an area ratio of a thin-film field-effect transistor used in a digital circuit to a thick-film field-effect transistor used in an analog circuit, scaled over generations in chronological order.

FIG. 6B is a correlation diagram between an area ratio (thin-film field-effect transistor used in digital circuit: thick-film field-effect transistor used in analog circuit) and a logic ratio (logic circuit: analog circuit).

FIG. 7 is a plan view schematically illustrating planar patterns of a first transistor and a second transistor mounted on a semiconductor device according to a second embodiment of the present technology.

FIG. 8 is a longitudinal cross-sectional view schematically illustrating a longitudinal cross-sectional structure taken along line a7-a7 in FIG. 7.

FIG. 9 is a plan view schematically illustrating planar patterns of a first transistor and a second transistor mounted on a semiconductor device according to a third embodiment of the present technology.

FIG. 10 is a longitudinal cross-sectional view schematically illustrating a longitudinal cross-sectional structure taken along line a9-a9 in FIG. 9.

FIG. 11 is a longitudinal cross-sectional view schematically illustrating a longitudinal cross-sectional structure taken along line c9-c9 in FIG. 9.

FIG. 12 is a longitudinal cross-sectional view schematically illustrating longitudinal cross-sectional structures of a first transistor and a second transistor mounted on a semiconductor device according to a fourth embodiment of the present technology.

FIG. 13 is a longitudinal cross-sectional view schematically illustrating longitudinal cross-sectional structures of a first transistor and a second transistor mounted on a semiconductor device according to a fifth embodiment of the present technology.

FIG. 14 is a longitudinal cross-sectional view schematically illustrating longitudinal cross-sectional structures of a first transistor and a resistive element mounted on a semiconductor device according to a sixth embodiment of the present technology.

FIG. 15 is a longitudinal cross-sectional view schematically illustrating longitudinal cross-sectional structures of a first transistor and a capacitive element mounted on a semiconductor device according to a seventh embodiment of the present technology.

FIG. 16 is a plan view of a main part, schematically illustrating a schematic configuration of a semiconductor device according to a ninth embodiment of the present technology.

FIG. 17 is a longitudinal cross-sectional view schematically illustrating a longitudinal cross-sectional structure taken along line a16-a16 in FIG. 16.

FIG. 18 is a diagram illustrating a configuration example of an IoT system according to the ninth embodiment of the present technology.

### MODE FOR CARRYING OUT THE INVENTION

Hereinafter, embodiments of the present technology will be described in detail with reference to the drawings.

In the illustration of the drawings referred to in the following description, the same or similar portions are denoted by the same or similar reference signs. It should be noted that the drawings are schematic, and a relationship between a thickness and a planar dimension, a ratio of the thicknesses between layers, and the like are different from actual ones. Therefore, specific thicknesses and dimensions should be determined in consideration of the following description.

Furthermore, it goes without saying that dimensional relationships and ratios are partly different between the drawings. Furthermore, the effects described herein are merely illustrative and not limiting, and there may also be other effects.

Furthermore, the following embodiments illustrate devices and methods for embodying the technical idea of the present technology and are not intended to limit the configuration to those described below. That is, various modifications can be made to the technical idea of the present technology within the technical scope described in the claims.

Furthermore, the definitions of directions such as up and down in the following description are merely for convenience of description and are not intended to limit the technical idea of the present technology. For example, it goes without saying that when an object is observed by rotating the object by 90°, the up and down are converted into left and right, and when the object is observed by rotating the object by 180°, the up and down are inverted.

Furthermore, in the following embodiments, a description will be given on the assumption that a first conductivity type is a p-type and a second conductivity type is an n-type; however, the conductivity types may be selected in reverse, that is, the first conductivity type may be the n-type and the second conductivity type may be the p-type.

Furthermore, in the following embodiments, in three directions orthogonal to each other in a space, a first direction and a second direction orthogonal to each other in the same plane are defined as an X direction and a Y direction, respectively, and a third direction orthogonal to the first direction and the second direction is defined as a Z direction. Then, in the following embodiments, a thickness direction of a three-dimensional material layer 3, which will be described later, will be described as the Z direction.

### First Embodiment

In the first embodiment, an example will be described where the present technology is applied to a semiconductor device including a first transistor with a low withstand voltage and a second transistor with a high withstand voltage, the first transistor and the second transistor having gate insulating films of different thicknesses.

### Configuration of Semiconductor Device

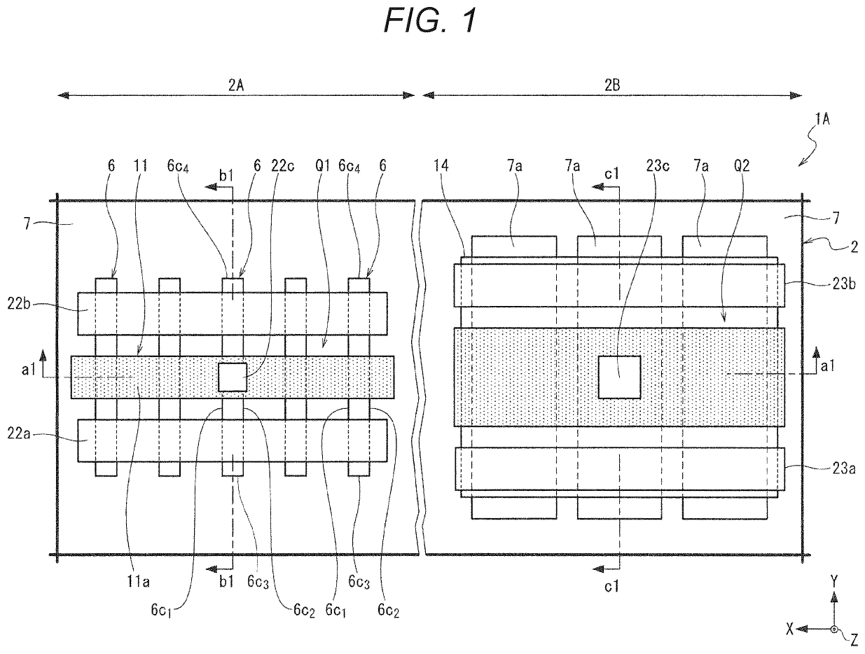

First, an overall configuration of a semiconductor device 1A will be described with reference to FIGS. 1 to 4.

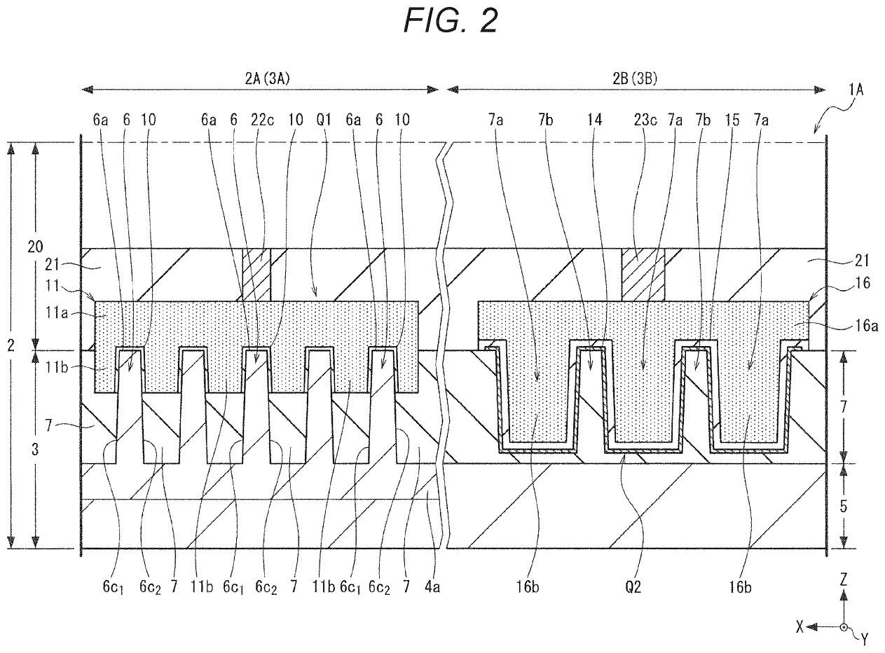

In FIG. 1, a multilayer wiring layer 20 illustrated in FIGS. 2 to 4 is not illustrated for convenience of description.

As illustrated in FIGS. 1 to 4, the semiconductor device 1A according to the first embodiment of the present technology primarily includes a substrate 2. The substrate 2 includes the three-dimensional material layer 3, a first field-effect transistor Q1 as a first transistor including the three-dimensional material layer 3, a two-dimensional material layer 14, and a second field-effect transistor Q2 as a second transistor including the two-dimensional material layer 14. Furthermore, the substrate 2 further includes an insulating layer 7 and the multilayer wiring layer 20 provided on a side of the three-dimensional material layer 3 to be described later remote from a base 5.

The substrate 2 includes a first region 2A and a second region 2B arranged two-dimensionally in a two-dimensional plane including the X direction and the Y direction. Then, the first field-effect transistor Q1 is provided in the first region 2A of the substrate 2, and the second field-effect transistor Q2 is provided in the second region 2B of the substrate 2 different from the first region 2A. In the first embodiment, the first field-effect transistor Q1 is used, for example, as a circuit element constituting a digital circuit, and the second field-effect transistor Q2 is used, for example, as a circuit element constituting an analog circuit. That is, the semiconductor device 1A according to the first embodiment includes the digital circuit including the first field-effect transistor Q1 and the analog circuit including the second field-effect transistor Q2.

Here, in the first embodiment, the first field-effect transistor Q1 corresponds to a specific example of the “first transistor” of the present technology, and the second field-effect transistor Q2 corresponds to a specific example of the “second transistor” of the present technology.

### Three-Dimensional Material Layer

As illustrated in FIGS. 2 to 4, the three-dimensional material layer 3 includes the base 5 that extends two-dimensionally in both the X and Y directions, and an island-shaped element formation portion (fin portion) 6 extending upward (Z direction) from the base 5. The element formation portion 6 extends in the Y direction and is provided for each first field-effect transistors Q1. The first embodiment has, but is not limited to, a configuration where, for example, an island group having five element formation portions 6 arranged in parallel at predetermined intervals in the X direction as one unit is provided for each first field-effect transistor Q1. FIG. 1 illustrates an example where the first field-effect transistor Q1 is provided on a one-to-one basis for each island group including five element formation portions 6.

As illustrated in FIGS. 1 to 4, each of the five element formation portions 6 has, for example, an upper surface 6a and four side surfaces 6c₁, 6c₂, 6c₃, and 6c₄, and has a rectangular planar shape having a longer side and a shorter side in plan view. Then, of each element formation portion 6, the thickness direction is the Z direction, the longitudinal direction is the Y direction, and the lateral direction is the X direction.

The upper surface 6a is located on a side of each element formation portion 6 remote from the base 5. Among the four side surfaces 6c₁, 6c₂, 6c₃, and 6c₄, two side surfaces 6c₁ and 6c₂ are located on opposite sides in the lateral direction (X direction), and the remaining two side surfaces 6c₃ and 6c₄ are located on opposite sides in the longitudinal direction (Y direction).

Each element formation portion 6 has a side remote from the upper surface 6a joined with the base 5.

Here, in the first embodiment, among the four side surfaces 6c₁, 6c₂, 6c₃, and 6c₄, the two side surfaces 6c₃ and 6c₄ located on opposite sides in the Y direction may be referred to as end surfaces 6c₃ and 6c₄.

Furthermore, the plan view refers to a case where the three-dimensional material layer 3 is viewed from a direction along the thickness direction (Z direction). Furthermore, the cross-sectional view refers to a case where the longitudinal cross section of the three-dimensional material layer 3 along the thickness direction (Z direction) is viewed from a direction (X direction or Y direction) orthogonal to the thickness direction (Z direction) of the three-dimensional material layer 3.

Each element formation portion 6 can be formed by selectively etching the three-dimensional material layer 3 to such a depth that the base 5 remains. That is, the base 5 and the element formation portions 6 include the three-dimensional material layer 3.

The three-dimensional material layer 3 includes atoms connected in three-dimensional directions, forming a crystal with a three-dimensional structure. The three-dimensional material layer 3 has, but is not limited to, for example, silicon (Si) as the semiconductor material, single crystal as the crystallinity, and intrinsic type (i-type) as the conductivity type. In the three-dimensional material layer 3, atoms are strongly bonded in three-dimensional directions, and carriers flow in any direction of the three-dimensional directions. As the material of the three-dimensional material layer 3, not only Si but also germanium (Ge), silicon germanium (SiGe), gallium arsenide (GaAs), indium phosphide (InP), or the like can be used.

The base 5 is provided across both the first region 2A and the second region 2B of the substrate 2. Then, the first embodiment has, but is not limited to, a configuration where the element formation portions 6 are selectively provided in the first region 2A of the substrate 2, and are not provided in the second region 2B.

Here, with reference to FIG. 2, the three-dimensional material layer 3 includes a first region 3A provided across the first region 2A of the substrate 2 and a second region 3B provided across the second region 2B of the substrate 2. Then, the first region 2A of the substrate 2 includes the first region 3A of the three-dimensional material layer 3, and the second region 2B of the substrate 2 includes the second region 3B of the three-dimensional material layer 3.

### Well Region

As illustrated in FIGS. 2 to 4, the three-dimensional material layer 3 is provided with a p-type well region 4a including, for example, a p-type semiconductor region, and the p-type well region 4a is selectively provided in the first region 3A of the three-dimensional material layer 3 and is not provided in the second region 3B, but the p-type well region 4a is not limited to such a configuration.

The p-type well region 4a is provided across all the element formation portions 6 in the first region 3A of the three-dimensional material layer 3 (the first region 2A of the substrate 2) and is provided all over a surface layer of the base 5 adjacent to the element formation portions 6. Then, the p-type well region 4a is separated from a back surface of the base 5 remote from the element formation portions 6.

### Insulating Layer

As illustrated in FIGS. 1 to 4, the insulating layer 7 is provided on a principal surface side (element formation portion 6 side) of the three-dimensional material layer 3 across both the first region 2A and the second region 2B of the substrate 2. The insulating layer 7 in the first region 2A is provided on the principal surface side of the three-dimensional material layer 3 so as to surround the element formation portions 6. The insulating layer 7 in the second region 2B is provided on the principal surface side of the three-dimensional material layer 3 so as to cover the entire base 5.

The insulating layer 7 has a surface layer on a side of the three-dimensional material layer 3 remote from the base 5 planarized across both the first region 2A and the second region 2B of the substrate 2, and has a film thickness approximately equal to a height of the element formation portions 6 of the three-dimensional material layer 3 (amount of protrusion from the base 5). The insulating layer 7 includes, for example, a silicon oxide (SiO₂) film.

### Uneven Portion

As illustrated in FIGS. 1 and 2, the insulating layer 7 in the second region 2B has recesses 7a and protrusions 7b alternately and repeatedly provided in one direction in the surface layer located on the side of the three-dimensional material layer 3 remote from the base 5. The recesses 7a and the protrusions 7b extend in the Y direction and are alternately and repeatedly arranged in the X direction, but the recesses 7a and the protrusions 7b are not limited to such a configuration. The recesses 7a and the protrusions 7b can be formed by selectively etching the surface layer of the insulating layer 7 remote from the three-dimensional material layer 3 (base 5).

The recesses 7a and the protrusions 7b are provided for each second field-effect transistor Q2. The first embodiment has, but is not limited to, a configuration where an uneven group including three recesses 7a and two protrusions 7b as one unit is provided for each second field-effect transistor Q2. FIG. 1 illustrates an example where the second field-effect transistor Q2 is provided on a one-to-one basis for each uneven group including three recesses 7a and two protrusions 7b.

### Two-Dimensional Material Layer

As illustrated in FIGS. 1 and 2, the two-dimensional material layer 14 is provided on a side of the insulating layer 7 remote from the three-dimensional material layer 3 in the second region 2B of the substrate 2. That is, the two-dimensional material layer 14 is provided above the three-dimensional material layer 3 with the insulating layer 7 interposed therebetween.

The two-dimensional material layer 14 has, but is not limited to, an uneven pattern continuously meandering along an uneven surface including the recesses 7a and the protrusions 7b of the insulating layer 7 to reflect the unevenness generated by the recesses 7a and the protrusions 7b of the insulating layer 7, for example. Specifically, the two-dimensional material layer 14 has an uneven pattern continuously meandering along an upper surface of the insulating layer 7 remote from the base 5, an inner wall surface including a bottom surface of each recess 7a, and an upper surface of each protrusion 7b to reflect the unevenness generated by the recesses 7a and the protrusions 7b of the insulating layer 7.

Then, in the first embodiment, since the two-dimensional material layer 14 is provided for each uneven group including the three recesses 7a and the two protrusions 7b, the two-dimensional material layer 14 is continuously provided over the three recesses 7a and the two protrusions 7b.

Here, the protrusions 7b each have an upper surface and side surfaces, but the side surfaces of the protrusions 7b belong to inner wall surfaces of the recesses 7a. In other words, the side surfaces of the protrusions 7b and side wall surfaces of the inner wall surfaces of the recesses 7a are shared.

The two-dimensional material layer 14 includes a two-dimensional material having a multilayer structure with a stack of two-dimensional unit layers. The two-dimensional material has high carrier mobility due to its two-dimensional structure.

Examples of the two-dimensional material may include a monolayer atomic material or a compound similar to the monolayer atomic material, and transition metal dichalcogenide.

The monolayer atomic material or the compound similar to the monolayer atomic material is a compound having a structure in which unit layers of a two-dimensional crystal structure formed by covalent bonds are stacked and bonded together by van der Waals forces.

Examples of such a compound may include graphene, black phosphorus, silicene, and hexagonal boron nitride (hBN). The two-dimensional material layer 14 may be formed as a monolayer film of one of these compounds or may be formed as a multilayer film of some of these compounds.

Furthermore, examples of the monolayer atomic material may include graphene, phospherene, and the like.

The transition metal dichalcogenide is a compound represented by the chemical formula MX₂. In the chemical formula MX₂, M represents a transition metal element such as Sc, Ti, V, Cr, Mn, Fe, Co, Ni, Cu, Ge, Zr, Nb, Mo, Ru, Rh, Pd, Sn, Hf, Ta, W, Re, Os, Ir, Pt, Au, Hg, or Pb, and X represents a chalcogenide element such as S, Se, or Te. More specifically, examples of the transition metal dichalcogenide may include CrS₂, CrSe₂, CrTe₂, HfS₂, HfSe₂, HfTe₂, MoS₂, MoSe₂, MoTe₂, NiS₂, NiSe₂, SnS₂, SnSe₂, TiS₂, TiSe₂, TiTe₂, WS₂, WSe₂, WTe₂, ZeTe₂, ZrS₂, ZrSe₂, or ZrTe₂. The two-dimensional material layer 14 may be formed as a monolayer film of one of these compounds or may be formed as a multilayer film of some of these compounds.

In particular, the two-dimensional material layer 14 preferably includes any two-dimensional material of MoS₂, MoSe₂, MoTe₂, WS₂, WSe₂, WTe₂, ZrS₂, ZrSe₂, ZeTe₂, HfSe₂, HfTe₂, graphene, or phospherene.

The two-dimensional material layer 14 preferably includes a two-dimensional material larger in band gap than the three-dimensional material layer 3. In the first embodiment, the three-dimensional material layer 3 includes Si, and the band gap of Si is 1.12 eV. Therefore, in a case where the three-dimensional material layer 3 includes Si, it is preferable to use the two-dimensional material layer 14 including a two-dimensional material larger in band gap than Si. In the first embodiment, for example, a two-dimensional material having a band gap of 3.0 eV is used as the two-dimensional material of the two-dimensional material layer 14.

The two-dimensional material layer 14 can be easily formed with a film thickness that reflects the unevenness generated by the recesses 7a and the protrusions 7b of the insulating layer 7. In the first embodiment, the two-dimensional material layer 14 has, but is not limited to, a film thickness of, for example, about 0.3 nm to 7 nm.

### First Field-Effect Transistor

The first field-effect transistor Q1 illustrated in FIG. 1 is of, but not limited to, an n-channel conductivity type, for example. Then, the first field-effect transistor Q1 includes a metal oxide semiconductor field-effect transistor (MOSFET) having a silicon oxide (SiO₂) film as a gate insulating film. The first field-effect transistor Q1 may be of a p-channel conductivity type. Alternatively, the first field-effect transistor Q1 may be a metal insulator semiconductor FET (MISFET) having a silicon nitride (Si₃N₄) film or a multilayer film (composite film) including a silicon nitride film and a silicon oxide film as a gate insulating film.

As illustrated in FIGS. 1 to 3, the first field-effect transistor Q1 is provided in the element formation portions 6 of the three-dimensional material layer 3.

The first field-effect transistor Q1 includes a channel formation portion 13 provided in each element formation portion 6, and a gate electrode 11 provided adjacent to (facing) the element formation portions 6 with a gate insulating film 10 interposed therebetween in the lateral direction (X direction) of the element formation portions 6. In the first embodiment, the gate electrode 11 is provided over each of the five element formation portions 6 belonging to one island group, but the gate electrode 11 is not limited to such a configuration. That is, the first field-effect transistor Q1 includes the three-dimensional material layer 3 used as the channel formation portion 13.

Furthermore, the first field-effect transistor Q1 further includes a pair of main electrode regions 12a and 12b that are provided separately from each other in each element formation portion 6 located on both sides of the gate electrode 11 in a gate length direction (Y direction) and function as a source region and a drain region, respectively.

Here, for convenience of description, one main electrode region 12a of the pair of main electrode regions 12a and 12b may be referred to as source region, and the other main electrode region 12b may be referred to as drain region 12b.

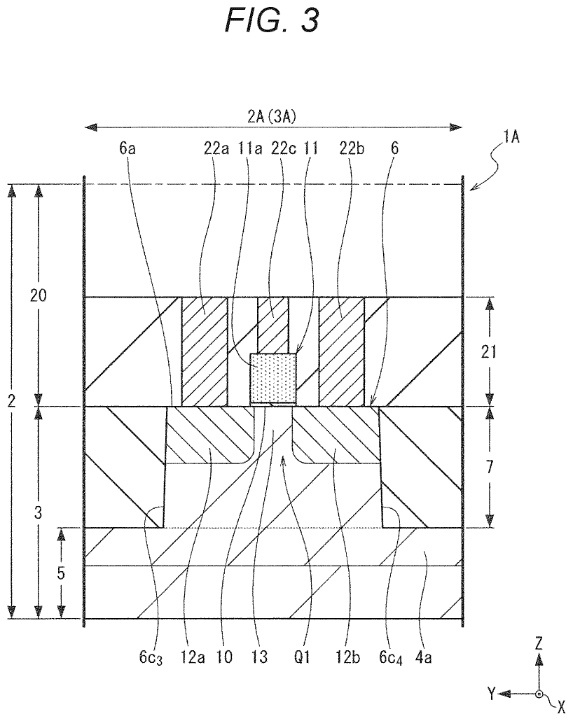

Furthermore, with reference to FIG. 3, a distance between the pair of main electrode regions 12a and 12b corresponds to a channel length (L) of the channel formation portion 13 (≈gate length (Lg) of the gate electrode 11), and a direction of the channel length is referred to as channel length direction (gate length direction). Then, a direction of a channel width (W) (gate width (Wg)) of the channel formation portion 13 is referred to as channel width direction (gate width direction). Then, in the first embodiment, as an example, since the pair of main electrode regions 12a and 12b are separated in the Y direction with the channel formation portion 13 interposed therebetween, the channel length direction is the Y direction.

### Main Electrode Region

Each of the pair of main electrode regions 12a and 12b illustrated in FIG. 3 includes, but is not limited to, an n-type semiconductor region formed in each element formation portion 6 in alignment with the gate electrode 11, for example. In the first embodiment, as an example, each of the pair of main electrode regions 12a and 12b includes one n-type semiconductor region, but each of the pair of main electrode regions 12a and 12b may include a plurality of n-type semiconductor regions including an extension region.

Although not illustrated in detail, each of the pair of main electrode regions 12a and 12b is provided on a one-to-one basis for each of the five element formation portions 6. Furthermore, the channel formation portion 13 is also provided on a one-to-one basis for each of the five element formation portions 6.

Note that, in the first embodiment, the case where each of the pair of main electrode regions 12a and 12b is formed at a depth less than the height of the element formation portions 6 has been described as an example, but each of the pair of main electrode regions 12a and 12b may be formed at a depth approximately equal to the height of the element formation portions 6.

### Gate Electrode

As illustrated in FIGS. 2 and 3, the gate electrode 11 includes a head 11a provided on the upper surface 6a of each element formation portion 6 with the gate insulating film 10 interposed therebetween, and a leg 11b joined with the head 11a and provided on the outer side of each of the two side surfaces 6c₁ and 6c₂ located on the opposite sides of each element formation portion 6 with the gate insulating film 10 interposed therebetween.

Here, it is preferable that the gate electrode 11 have the legs 11b placed on both sides of each element formation portion 6 in the lateral direction (X direction). In this case, the number of the legs 11b of the gate electrode 11 is “n+1” when the number of the element formation portions 6 is “n”. In the first embodiment, since the five element formation portions 6 are provided, the gate electrode 11 has six legs 11b.

As illustrated in FIG. 2, the head 11a of the gate electrode 11 is located above the upper surface 6a of each element formation portion 6 and extends over the five element formation portions 6. Then, the head 11a of the gate electrode 11 is covered with an insulating layer 21 included in the multilayer wiring layer 20.

As illustrated in FIG. 2, each of the six legs 11b of the gate electrode 11 is located below the upper surface 6a of each element formation portion 6, and is surrounded by the insulating layer 7 together with the element formation portions 6. The gate electrode 11 including the head 11a and the legs 11b includes, for example, a polycrystalline silicon (doped polysilicon) film doped with impurities that reduce the resistance value.

Note that, as the material of the gate electrode 11, for example, TiAl, TaN, TiN, high-k, or an interfacial layer oxide can be used.

### Gate Insulating Film

As illustrated in FIG. 2, the gate insulating film 10 is provided over the upper surface 6a and the two side surfaces 6c₁ and 6c₂ of each element formation portion 6. In the first embodiment, since the five element formation portions 6 are provided for each first field-effect transistor Q1, the gate insulating film 10 is provided over the upper surface 5a and each of the two side surfaces 6c₁ and 6cb₂ of each of the five element formation portions 6. The gate insulating film 10 includes, for example, a silicon oxide film.

### Three-Dimensional Structure

As illustrated in FIGS. 2 and 3, in the first field-effect transistor Q1 of the first embodiment, the gate electrode 11 is provided on the island-shaped element formation portion 6 as a fin portion with the gate insulating film 10 interposed therebetween. That is, the first field-effect transistor Q1 has a so-called fin-shaped three-dimensional structure.

In such a first fin field-effect transistor Q1, the length between the pair of main electrode regions 12a and 12b is the channel length L (≈gate length Lg). Then, in the longitudinal cross section along the lateral direction (X direction) of the element formation portions 6, a value obtained by multiplying the length of the gate electrode 11 facing each element formation portion 6 with the gate insulating film 10 interposed therebetween by the number of the element formation portions 6 is the channel width W (≈gate width).

Therefore, for the first fin field-effect transistor Q1, an increase in the width of each element formation portion 6 in the lateral direction (X direction) and an increase in the height of each element formation portion 6 in the Z direction cause an increase in the channel width W, so that it is possible to increase a channel area (the channel length L×the channel width W). Then, it is possible for the first fin field-effect transistor Q1 to increase the channel area (the channel length L×the channel width W) by increasing the number of the element formation portions 6.

In the first embodiment, the case where the first field-effect transistor Q1 is provided on a one-to-one basis for each island group having five element formation portions 6 as one unit has been described, but the number of the element formation portions 6 may be one or more.

The first field-effect transistor Q1 can be of, for example, an enhancement type (normally-off type) in which a drain current flows by applying a gate voltage higher than or equal to a threshold voltage to the gate electrode 11. Alternatively, the first field-effect transistor Q1 can be of, for example, a depression type (normally-off type) in which a drain current flows even without applying a voltage to the gate electrode 11. In the first embodiment, the first field-effect transistor Q1 is of, but not limited to, an enhancement type. In a case where the first field-effect transistor Q1 is of an enhancement type, a channel (inversion layer) electrically connecting the pair of main electrode regions 12a and 12b is formed (induced) in the channel formation portion 13 (element formation portion 6) by a voltage applied to the gate electrode 11, and a current (drain current) flows from a drain region side (e.g., a main electrode region 12b side) to a source region side (e.g., a main electrode region 12a side) through the channel of the channel formation portion 13.

In a case where the first field-effect transistor Q1 has a fin shape, a channel is formed on the upper surface 6a and the two side surfaces 6c₁ and 6c₂ of each element formation portion 6. Therefore, the first fin field-effect transistor Q1 allows, when an occupied area (footprint) is the same, a large drain current to flow and an increase in transconductance gm as compared with planar field-effect transistors. It is therefore possible for the first fin field-effect transistor Q1 to increase the operation speed as compared with planar field-effect transistors.

### Second Field-Effect Transistor

The second field-effect transistor Q2 illustrated in FIG. 1 is of, but not limited to, an n-channel conductivity type, for example. Then, the second field-effect transistor Q2 includes a MOSFET having a silicon oxide (SiO₂) film as a gate insulating film. The second field-effect transistor Q2 may be of a p-channel conductivity type. Alternatively, the second field-effect transistor Q2 may be a MISFET having a silicon nitride (Si₃N₄) film or a multilayer film (composite film) including a silicon nitride film and a silicon oxide film as a gate insulating film.

As illustrated in FIGS. 1, 2, and 4, the second field-effect transistor Q2 is provided in the two-dimensional material layer 14.

The second field-effect transistor Q2 includes a channel formation portion 18 provided in the two-dimensional material layer 14, a gate insulating film 15 provided on a side of the two-dimensional material layer 14 remote from the insulating layer 7 so as to face the channel formation portion 18, and a gate electrode 16 provided to face the channel formation portion 18 with the gate insulating film 15 interposed therebetween. That is, the second field-effect transistor Q2 includes the two-dimensional material layer 14 used as the channel formation portion 18. In the first embodiment, the gate electrode 16 is provided over three recesses 7a and two protrusions 7b belonging to one uneven group, but the gate electrode 16 is not limited to such a configuration.

Furthermore, the second field-effect transistor Q2 further includes a pair of main electrode regions 17a and 17b that are provided separately from each other in the two-dimensional material layer 14 located on both sides of the gate electrode 16 in a gate length direction (Y direction) and function as a source region and a drain region, respectively. The source region and the drain region can also reduce resistance to the gate electrode 16 by a method such as chemical doping of adsorbing impurities on or under the two-dimensional material layer 14.

Here, for convenience of description, one main electrode region 17a of the pair of main electrode regions 17a and 17b may be referred to as source region, and the other main electrode region 17b may be referred to as drain region 12b.

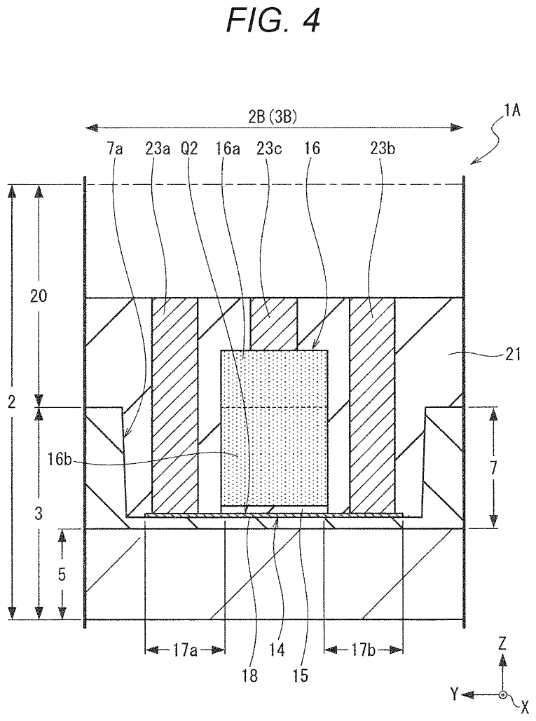

Furthermore, with reference to FIG. 4, a distance between the pair of main electrode regions 17a and 17b corresponds to a channel length (L) of the channel formation portion 18 (≈gate length (Lg) of the gate electrode 16), and a direction of the channel length is referred to as channel length direction (gate length direction). Then, a direction of a channel width (W) (gate width (Wg)) of the channel formation portion 18 is referred to as channel width direction (gate width direction). Then, in the first embodiment, as an example, since the pair of main electrode regions 17a and 17b are separated in the Y direction with the channel formation portion 18 interposed therebetween, the channel length direction is the Y direction.

### Main Electrode Region

Each of the pair of main electrode regions 17a and 17b illustrated in FIG. 4 includes, but is not limited to, an n-type semiconductor region formed in the two-dimensional material layer 14 in alignment with the gate electrode 16, for example. In the first embodiment, as an example, each of the pair of main electrode regions 17a and 17b includes one n-type semiconductor region, but each of the pair of main electrode regions 17a and 17b may include a plurality of n-type semiconductor regions.

Although not illustrated in detail, each of the pair of main electrode regions 17a and 17b is provided continuously in the two-dimensional material layer 14 over the three recesses 7a. Furthermore, the channel formation portion 18 is also provided continuously in the two-dimensional material layer 14 over the three recesses 7a.

### Gate Electrode

As illustrated in FIG. 2, the two-dimensional material layer 14 and the gate insulating film 15 are each provided along the uneven surface including the recesses 7a and the protrusions 7b of the insulating layer 7. The gate electrode 16 includes a head 16a provided on the upper surface of the insulating layer 7 remote from the three-dimensional material layer 3 (base 5) with the two-dimensional material layer 14 and the gate insulating film 15 interposed therebetween, and a leg 16b joined with the head 16a and provided in the corresponding recess 7a of the insulating layer 7 with the two-dimensional material layer 14 and the gate insulating film 15 interposed therebetween.

Here, as illustrated in FIG. 2, it is preferable that the gate electrode 16 have its legs 16b placed on both sides of each protrusion 7b in the lateral direction (X direction). In this case, the number of the legs 16b of the gate electrode 16 is “m+1” when the number of the protrusions 7b of the insulating layer 7 is “m”. In the first embodiment, since two protrusions 7b are provided, the gate electrode 16 has three legs 11b.

Note that in a case where there is one recess 7a and there is no protrusion 7b, the gate electrode 16 has one leg 16b.

As illustrated in FIG. 2, the head 16a of the gate electrode 16 is located above the upper surface of each protrusion 7b of the insulating layer 7, and extends over the three recesses 7a and the two protrusions 7b in the lateral direction (X direction) of the recesses 7a and the protrusions 7b. Then, the head 16a of the gate electrode 16 is covered with the insulating layer 21 included in the multilayer wiring layer 20.

As illustrated in FIG. 2, each of the three legs 16b of the gate electrode 16 is provided in the corresponding recess 7a of the insulating layer 7 with the two-dimensional material layer 14 and the gate insulating film 15 interposed therebetween and is surrounded by the insulating layer 7. The gate electrode 16 including the head 16a and the legs 16b includes, for example, a polycrystalline silicon (doped polysilicon) film doped with impurities that reduce the resistance value.

### Gate Insulating Film

As illustrated in FIG. 2, the gate insulating film 15 is provided on a side of the two-dimensional material layer 14 remote from the insulating layer 7. Then, the gate insulating film 15 has an uneven pattern continuously meandering along the uneven surface including the recesses 7a and the protrusions 7b of the insulating layer 7 with the two-dimensional material layer 14 interposed therebetween to reflect the unevenness generated by the recesses 7a and the protrusions 7b of the insulating layer 7 together with the two-dimensional material layer 14. Specifically, in a manner similar to the two-dimensional material layer 14, the gate insulating film 15 has an uneven pattern continuously meandering along the upper surface of the insulating layer 7 remote from the base 5, the inner wall surface including the bottom surface of each recess 7a, and the upper surface of each protrusion 7b to reflect the unevenness generated by the recesses 7a and the protrusions 7b of the insulating layer 7.

Then, in the first embodiment, since the gate insulating film 15 is provided for each uneven group including the three recesses 7a and the two protrusions 7b with the two-dimensional material layer 14 interposed therebetween, the gate insulating film 15 is continuously provided over the three recesses 7a and the two protrusions 7b together with the two-dimensional material layer 14. The gate insulating film 15 includes, for example, a silicon oxide film.

### Three-Dimensional Structure

As illustrated in FIGS. 2 and 4, in the second field-effect transistor Q2 of the first embodiment, the two-dimensional material layer 14, the gate insulating film 15, and the gate electrode 16 are each provided over the recesses 7a and the protrusions 7b of the insulating layer 7. That is, the second field-effect transistor Q2 has a three-dimensional structure where the two-dimensional material layer 14 and the gate insulating film 15 meander in the Z direction.

In such a second field-effect transistor Q2, the length between the pair of main electrode regions 17a and 17b is the channel length L (≈gate length Lg). Then, in the longitudinal cross section along the lateral direction (X direction) of the recesses 7a and the protrusions 7b of the insulating layer 7, a value obtained by multiplying the length of the gate electrode 16 facing the two-dimensional material layer 14 with the gate insulating film 15 interposed therebetween by the number of the recesses 7a is the channel width W (≈gate width).

Therefore, for the second field-effect transistor Q2, an increase in the width of each of the recesses 7a and the protrusions 7b of the insulating layer 7 in the lateral direction (X direction) and increases in the depth of each recess 7a and the height of each protrusion cause an increase in the channel width W, so that it is possible to increase a channel area (the channel length L×the channel width W), in a manner similar to the first field-effect transistor Q1. Then, it is possible for the second field-effect transistor Q2 to increase the channel area (the channel length L×the channel width W) by increasing the number of the recesses 7a and protrusions 7b, in a manner similar to the first field-effect transistor Q1.

In the first embodiment, the case where the second field-effect transistor Q2 is provided on a one-to-one basis for each uneven group including three recesses 7a and two protrusions 7b as one unit has been described, but the number of the recesses 7a may be one or more. The number of the protrusions 7b is “m−1” when the number of the recesses 7a is “m”.

The second field-effect transistor Q2 can be of, for example, an enhancement type (normally-off type) in which a drain current flows by applying a gate voltage higher than or equal to a threshold voltage to the gate electrode 16. Alternatively, the second field-effect transistor Q2 can be of, for example, a depression type (normally-off type) in which a drain current flows even without applying a voltage to the gate electrode 16. In the first embodiment, the second field-effect transistor Q2 is of, but not limited to, an enhancement type. In a case where the second field-effect transistor Q2 is of an enhancement type, a channel (inversion layer) electrically connecting the pair of main electrode regions 17a and 17b is formed (induced) in the channel formation portion 18 by a voltage applied to the gate electrode 16, and a current (drain current) flows from a drain region side (e.g., a main electrode region 17b side) to a source region side (e.g., a main electrode region 17a side) through the channel of the channel formation portion 18.

The second field-effect transistor Q2 has a three-dimensional structure with an uneven pattern where the two-dimensional material layer 14 and the gate insulating film 15 continuously meander along the uneven surface including the recesses 7a and the protrusions 7b of the insulating layer 7 to reflect the unevenness generated by the recesses 7a and the protrusions 7b of the insulating layer 7. Therefore, the second field-effect transistor Q2 allows, when an occupied area (footprint) is the same, a large drain current to flow and an increase in transconductance gm as compared with planar field-effect transistors. It is therefore possible for the field-effect transistor Q2 having the three-dimensional structure to increase the operation speed as compared with planar field-effect transistors.

### Comparison Between First Field-Effect Transistor and Second Field-Effect Transistor

The second field-effect transistor Q2 illustrated in FIGS. 1, 2, and 4 is mainly used as a circuit element constituting an analog circuit, and the first field-effect transistor Q1 illustrated in FIGS. 1 to 3 is mainly used as a circuit element constituting a digital circuit.

Then, the second field-effect transistor Q2 is higher in drive voltage (power supply voltage (Vdd)) than the first field-effect transistor Q1 and is also higher in withstand voltage. That is, the gate insulating film 15 of the second field-effect transistor Q2 is thicker than the gate insulating film 10 of the first field-effect transistor Q1.

In the first embodiment, the gate insulating film 15 of the second field-effect transistor Q2 has, but is not limited to, a film thickness of, for example, about 3 nm to 8 nm. On the other hand, the gate insulating film 10 of the first field-effect transistor Q1 has a film thickness of, for example, about 1 nm to ₂ nm. Then, the drive voltage (power supply voltage (Vdd)) of the second field-effect transistor Q2 is, for example, about 1.5 V to 3 V, and the drive voltage (power supply voltage (Vdd)) of the first field-effect transistor Q1 is, for example, about 0.5 V to 1 V.

Here, as a relative comparison between the second field-effect transistor Q2 and the first field-effect transistor Q1, the second field-effect transistor Q2 may also be referred to as high withstand voltage type, high voltage (HV) type, or core type, and the first field-effect transistor Q1 may also be referred to as low withstand voltage type, low voltage (LV) type, or IO type.

The second field-effect transistor Q2 may also be referred to as thick-film type, and the direction of the first field-effect transistor Q1 may also be referred to as thin-film type.

### Multilayer Wiring Layer

As illustrated in FIGS. 2 to 4, the multilayer wiring layer 20 is provided on a side of the insulating layer 7 remote from the three-dimensional material layer 3, in other words, on the element formation portion 6 side of the three-dimensional material layer 3. Although not illustrated in detail, the multilayer wiring layer 20 has a multilayer structure including multiple insulating layers and wiring layers alternately stacked. In FIGS. 2 to 4, the insulating layer 21 that is the lowest layer closest to the three-dimensional material layer 3 is illustrated as an insulating layer included in the multilayer wiring layer 20. The insulating layer 21 is provided across both the first region 3A and the second region 3B of the three-dimensional material layer 3 (the first region 2A and the second region 2B of the substrate 2). The insulating layer 21 covers the first field-effect transistor Q1 provided in the element formation portions 6 in the first region 3A of the three-dimensional material layer 3, and covers the second field-effect transistor Q2 provided in the two-dimensional material layer 14 in the second region 3B of the three-dimensional material layer 3.

As the material of the insulating layer included in the multilayer wiring layer 20, for example, silicon oxide (SiO₂) can be used. Furthermore, as the material of the wiring layer included in the multilayer wiring layer 20, for example, a metal material such as aluminum (Al) or copper (Cu), an alloy material mainly containing Al or Cu, or the like can be used.

As illustrated in FIGS. 2 to 4, the multilayer wiring layer 20 includes contact electrodes 22a, 22b, 22c, 23a, 23b, and 23c provided in the insulating layer 21. As the material of the contact electrodes 22a, 22b, 22c, 23a, 23b, and 23c, for example, a high melting point metal such as titanium (Ti) or tungsten (W) can be used.

### Contact Electrode

As illustrated in FIGS. 2 and 3, the contact electrode 22c has one end electrically and mechanically connected to the gate electrode 11 of the first field-effect transistor Q1. Although not illustrated in detail, the contact electrode 22c has the other end electrically connected to wiring formed in the wiring layer of the multilayer wiring layer 20.

As illustrated in FIG. 3, the contact electrode 22a has one end electrically and mechanically connected to the main electrode region 12a that is one of the main electrode regions of the first field-effect transistor Q1. Then, although not illustrated in detail, the contact electrode 22a has the other end electrically and mechanically connected to wiring formed in the wiring layer of the multilayer wiring layer 20.

As illustrated in FIG. 3, the contact electrode 22b has one end electrically and mechanically connected to the main electrode region 12b that is the other of the main electrode regions of the first field-effect transistor Q1. Then, although not illustrated in detail, the contact electrode 22b has the other end electrically and mechanically connected to wiring formed in the wiring layer of the multilayer wiring layer.

As illustrated in FIG. 1, each of the contact electrodes 22a and 22b extends in the X direction and is provided over each of the five element formation portions 6 belonging to one island group. Then, the contact electrode 22a is electrically and mechanically connected to the main electrode region 12a (see FIG. 3) that is one of the main electrode regions of the first field-effect transistor Q1 provided for each of the five element formation portions 6 belonging to one island group. Then, the contact electrode 22b is also electrically and mechanically connected to the main electrode region 12b (see FIG. 3) that is the other of the main electrode regions of the first field-effect transistor Q1 provided for each of the five element formation portions 6 belonging to one island group.

As illustrated in FIGS. 2 and 4, the contact electrode 23c has one end electrically and mechanically connected to the gate electrode 16 of the second field-effect transistor Q2. Then, although not illustrated in detail, the contact electrode 23c has the other end electrically and mechanically connected to wiring formed in the wiring layer of the multilayer wiring layer 20.

As illustrated in FIG. 4, the contact electrode 23a has one end electrically and mechanically connected to the main electrode region 17a that is one of the main electrode regions of the second field-effect transistor Q2. Then, although not illustrated in detail, the contact electrode 23a has the other end electrically and mechanically connected to wiring formed in the wiring layer of the multilayer wiring layer 20.

As illustrated in FIG. 4, the contact electrode 23b has one end electrically and mechanically connected to the main electrode region 17b that is other of the main electrode regions of the second field-effect transistor Q2. Then, although not illustrated in detail, the contact electrode 23b has the other end electrically and mechanically connected to wiring formed in the wiring layer of the multilayer wiring layer.

As illustrated in FIG. 1, each of the contact electrodes 23a and 23b extends in the X direction and is provided over three recesses 7a and two protrusions 7b belonging to one uneven group of the insulating layer 7. Then, the contact electrode 23a is electrically and mechanically connected to the main electrode region 17a (see FIG. 4) that is one of the main electrode regions of the second field-effect transistor Q2 over three recesses 7a and two protrusions 7b belonging to one uneven group of the insulating layer 7. Then, the contact electrode 23b is also electrically and mechanically connected to the main electrode region 17b (see FIG. 4) that is the other of the main electrode regions of the second field-effect transistor Q2 over three recesses 7a and two protrusions 7b belonging to one uneven group of the insulating layer 7.

Note that the contact electrodes 22a and 22b may be provided for each element formation portion 6 belonging to one island group. Furthermore, the contact electrodes 23a and 23b may also be provided for each recess 7a of the insulating layer 7 or each protrusion 7b of the insulating layer 7 belonging to one uneven group.

### Method for Manufacturing Semiconductor Device

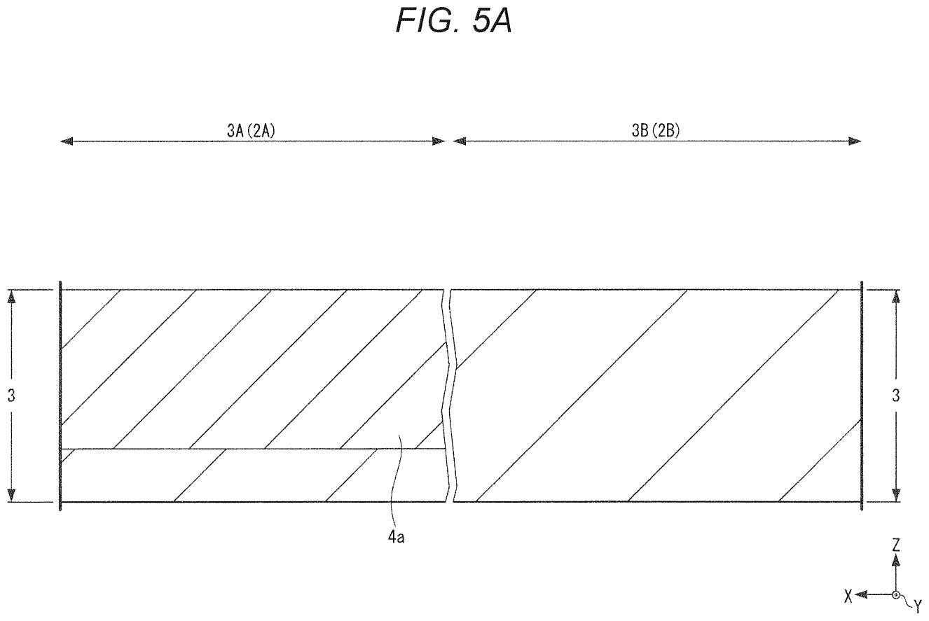

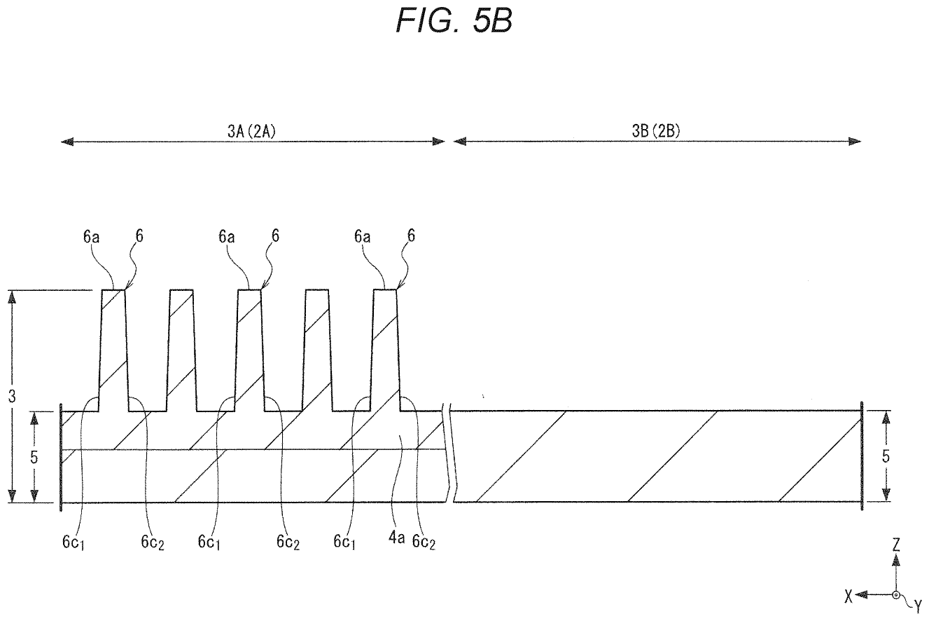

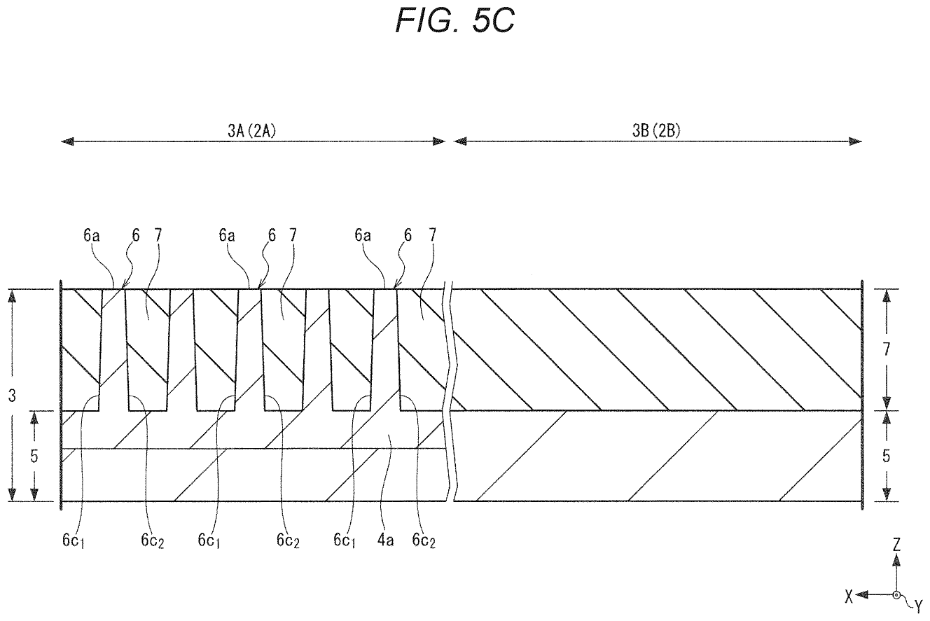

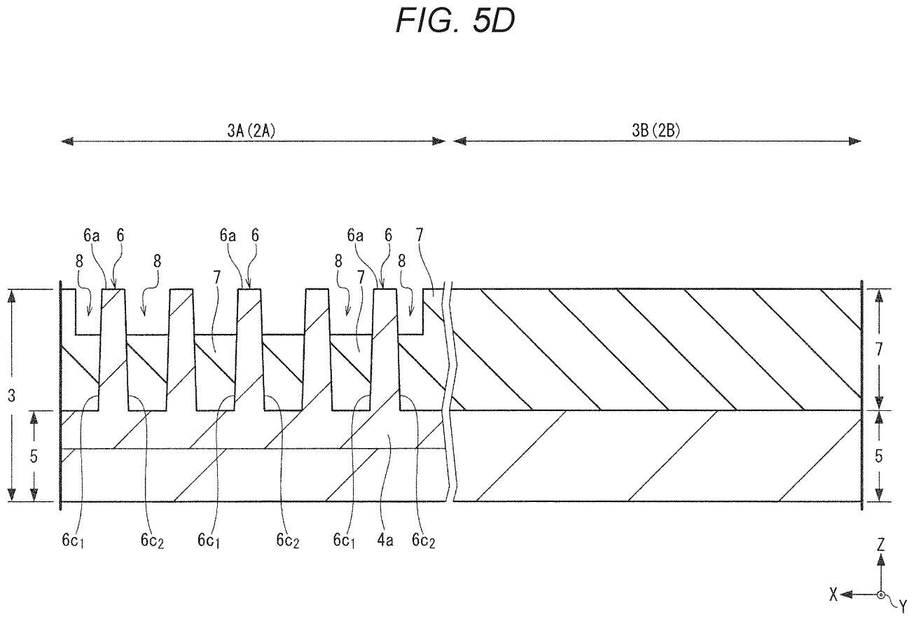

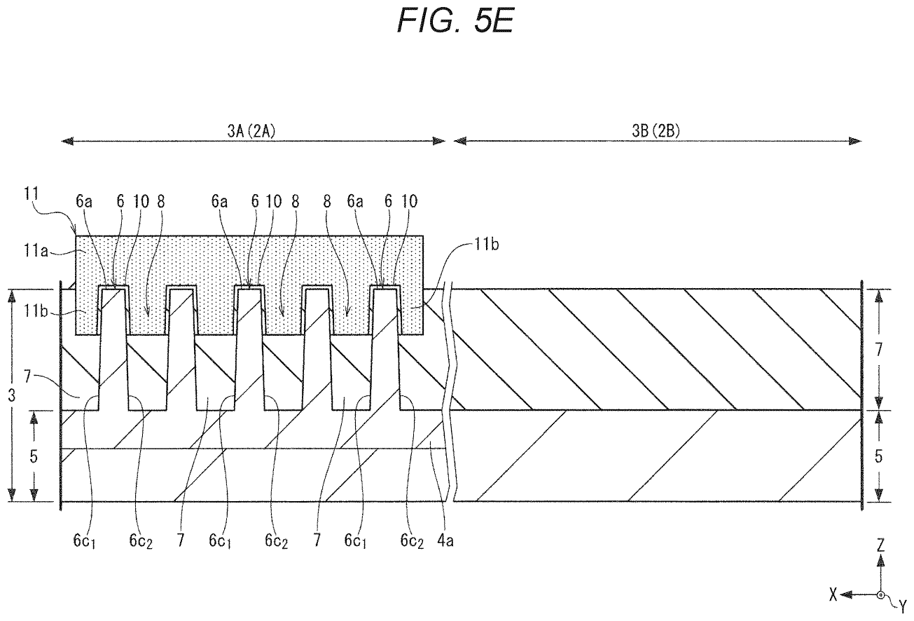

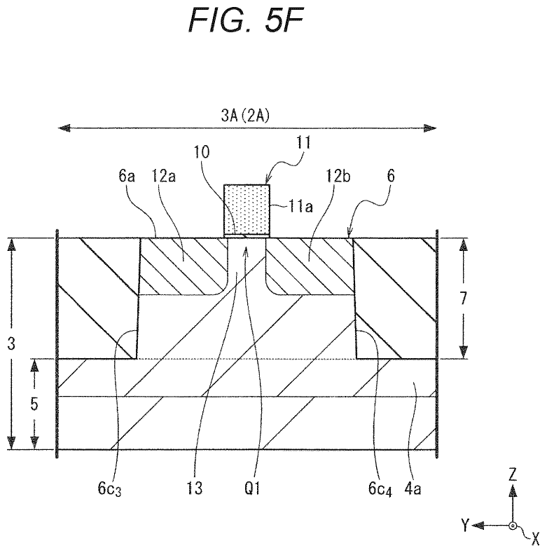

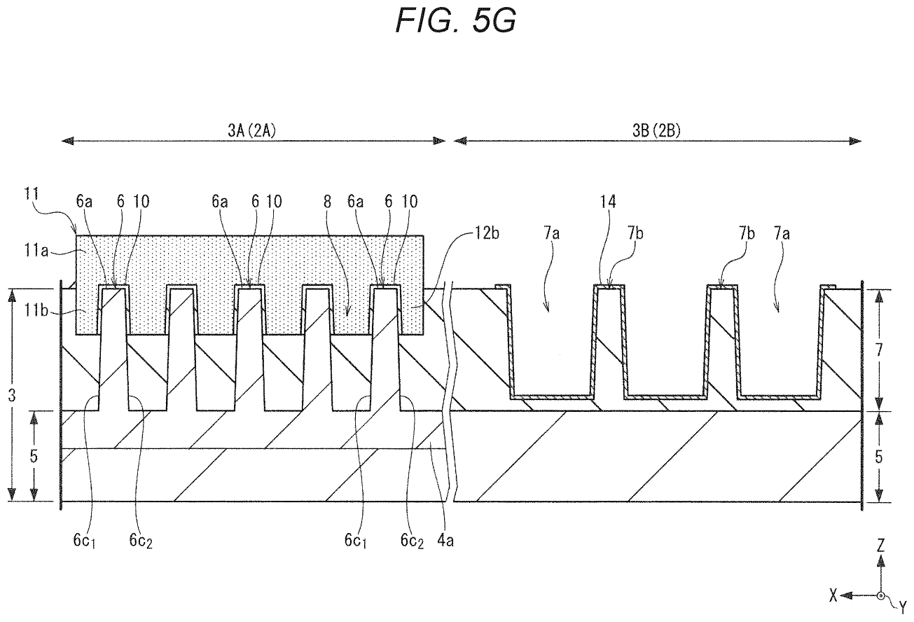

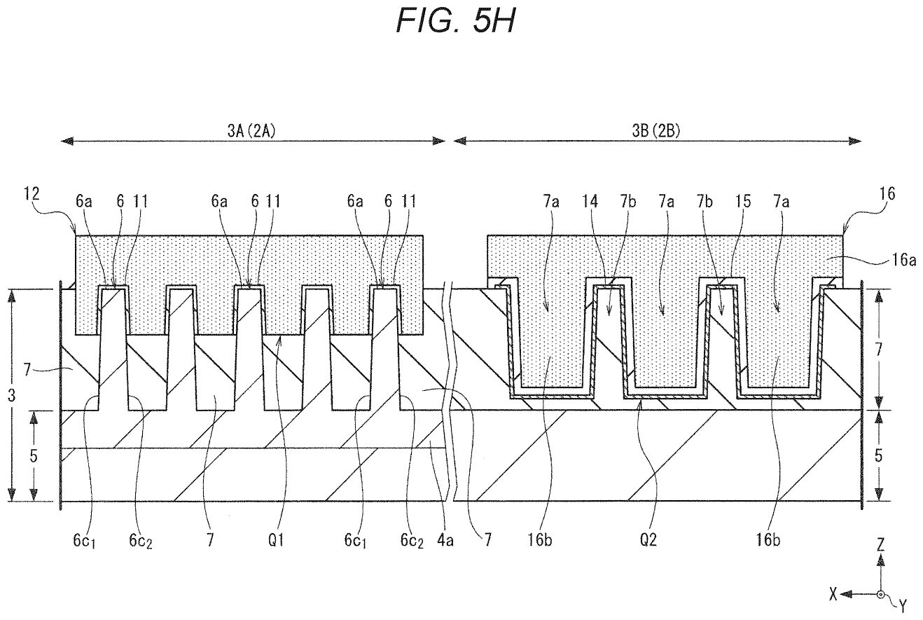

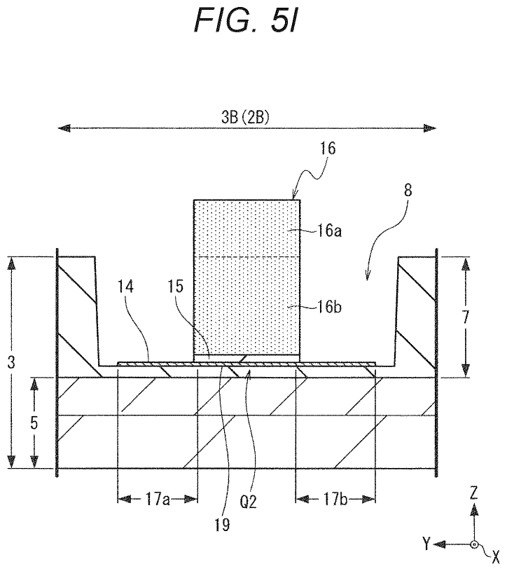

Next, a method for manufacturing the semiconductor device 1A according to the first embodiment will be described with reference to FIGS. 5A to 5I.

FIGS. 5A to 5E, 5G, and 5H are longitudinal cross-sectional views each illustrating a longitudinal cross-sectional structure taken along line a1-a1 in FIG. 1. Then, FIG. 5F is a longitudinal cross-sectional view illustrating a longitudinal cross-sectional structure taken along line b1-b1 in FIG. 1. Then, FIG. 5I is a longitudinal cross-sectional view illustrating a longitudinal cross-sectional structure taken along line c1-c1 in FIG. 1.

In the first embodiment, how to form the first field-effect transistor Q1 and the second field-effect transistor Q2 included in the manufacturing of the semiconductor device 1A will be mainly described.

First, the three-dimensional material layer 3 is prepared, and then, as illustrated in FIG. 5A, the p-type well region 4a including a p-type semiconductor region is selectively formed in the first region 3A of the three-dimensional material layer 3. As an example, the p-type well region 4a can be formed by selectively implanting boron ions (B⁺) as p-type impurities into the first region 3A of the three-dimensional material layer 3 and then diffusing the implanted boron ions (B⁺) through thermal diffusion treatment. In this embodiment, the p-type well region 4a is not formed in the second region 3B of the three-dimensional material layer 3 different from the first region 3A. The first region 3A of the three-dimensional material layer 3 is included in the first region 2A of the substrate 2 illustrated in FIG. 2, and the second region 3B of the three-dimensional material layer 3 is included in the second region 2B of the substrate 2 illustrated in FIG. 2.

The three-dimensional material layer 3 can include, but is not limited to, a semiconductor substrate with, for example, silicon (Si) as the semiconductor material, single crystal as the crystallinity, and intrinsic type (i-type) as the conductivity type.

Next, the surface layer on the principal surface side of the three-dimensional material layer 3 is selectively etched to form the base 5 and the island-shaped element formation portion (fin portion) 6 protruding upward from the base 5 as illustrated in FIG. 5B. The base 5 is formed across both the first region 3A and the second region 3B of the three-dimensional material layer 3. For example, five element formation portions 6 are formed for each island group in the first region 3A of the three-dimensional material layer 3. The island group including the five element formation portions 6 is formed for each formation region of the first field-effect transistor Q1.

Each of the five element formation portions 6 has, for example, the upper surface 6a and the four side surfaces 6c₁, 6c₂, 6c₃, and 6c₄ (see FIGS. 1 to 3) and is formed in a rectangular three-dimensional shape (island shape) having a longer side and a shorter side in plan view.

Each element formation portion 6 can be formed by selectively etching the three-dimensional material layer 3 to such a depth that the base 5 remains. Therefore, each element formation portion 6 is formed with a side opposite to the upper surface 6a joined with the base 5, and includes the three-dimensional material layer 3.

Next, as illustrated in FIG. 5C, the insulating layer 7 is formed on the element formation portion 6 side of the three-dimensional material layer 3 to surround the element formation portions 6 and cover the base 5 of the three-dimensional material layer 3 across the first region 3A and the second region 3B of the three-dimensional material layer 3. As an example, it is possible to form the insulating layer 7 by forming an insulating film such as a silicon oxide film on the entire surface covering the base 5 of the three-dimensional material layer 3 and the element formation portions 6 by a known film formation method, and then removing a surface layer of the insulating film remote from the three-dimensional material layer 3 by a CMP method to such a depth that the upper surface of each element formation portion 6 is exposed.

In this step, the surface layer of the insulating layer 7 remote from the base 5 is planarized, and the surface layer of the insulating layer 7 and the upper surface 6a of each element formation portion 6 are roughly flush with each other. Then, the insulating layer 7 is formed with a film thickness approximately equal to the height (protrusion amount) of the element formation portions 6.

Next, the insulating layer 7 located on the outer side of each element formation portion 6 in the lateral direction (X direction) is selectively removed, and as illustrated in FIG. 5D, a recessed portion 8 that selectively exposes the two side surfaces 6c₁ and 6c₂ of each element formation portion 6 is formed on the outer side of each element formation portion 6 in the lateral direction (X direction).

Two recessed portions 8 are formed for each element formation portion 6 and are each shared by two element formation portions 6 adjacent to each other. In the first embodiment, since five element formation portions 6 constitute one island group, six recessed portions 8 are formed.

Furthermore, each recessed portion 8 is formed at, for example, a depth less than half the height of the element formation portions 6, but the recessed portion 8 is not limited to such a configuration. The recessed portions 8 define the width of the legs 11b of the gate electrode 11 in the gate length direction (Y direction) of the gate electrode 11 to be described later.

Next, as illustrated in FIG. 5E, the gate insulating film 10 and the gate electrode 11 are formed across the first region 3A of the three-dimensional material layer 3.

The gate insulating film 10 is formed over the upper surface 6a and the two side surfaces 6c₁ and 6c₂ of each element formation portion 6. It is possible to form the gate insulating film 10 by forming a silicon oxide film by, for example, a thermal oxidation method or a deposition method. The gate insulating film 10 is formed with a film thickness of, for example, about 1 nm to 2 nm.

It is possible to form the gate electrode 11 by forming the gate insulating film 10, then forming a conductive film on the entire surface of the three-dimensional material layer 3 including the inside of each recessed portion 8, the upper surface 6a of each element formation portion 6, and the insulating layer 7, and then patterning the conductive film using a known photolithography technique and dry etching technique. As the conductive film, for example, a polycrystalline silicon (doped polysilicon) film into which impurities that reduce the resistance value are introduced during or after film formation can be used.

In this step, the gate insulating film 10 is interposed between the gate electrode 11 and the element formation portions 6.

Furthermore, in this step, the gate electrode 11 is formed in a shape having the head 11a provided on the upper surface 6a of each element formation portion 6 with the gate insulating film 10 interposed therebetween, and the leg 11b joined with the head 11a and provided on the outer side of each of the two side surfaces 6b₁ and 6b₂ located on the opposite sides of each element formation portion 6 in the lateral direction (X direction) with the gate insulating film 10 interposed therebetween.

The head 11a is located above the upper surface 6a of each element formation portion 6 and extends over the six recessed portions 8 and the five element formation portions 6 in the lateral direction (X direction) of the element formation portions 6.

The leg 11b is formed in each of the six recessed portions 8 and has a side opposite to the tip side connected to the head 11a.

Next, as illustrated in FIG. 5F, the pair of main electrode regions 12a and 12b each including an n-type semiconductor region are formed in each element formation portion 6 located on both sides of the gate electrode 11 in the gate length direction (Y direction). It is possible to form the pair of main electrode regions 12a and 12b by using the gate electrode 11 and the insulating layer 7 as masks for impurity introduction, implanting, for example, arsenic ions (As⁺) or phosphorus ions (P⁺) as n-type impurities into each element formation portion 6 located on both sides of the gate electrode 11 in the gate length direction (Y direction), and then subjecting the element formation portions 6 to heat treatment to activate the impurities. The pair of main electrode regions 12a and 12b are formed so as to be aligned with the gate electrode 11 and separated from each other, and function as a source region and a drain region, respectively. Each of the pair of main electrode regions 12a and 12b is formed in each of the five element formation portions 6.

Through this step, the channel formation portion 13 is formed in each element formation portion 6 between the pair of main electrode regions 12a and 12b.

Furthermore, through this step, the first field-effect transistor Q1 including the element formation portions 6, the gate insulating film 10, the gate electrode 11, and the pair of main electrode regions 12a and 12b is formed.

Next, as illustrated in FIG. 5G, the uneven group including recesses 7a and protrusions 7b and the two-dimensional material layer 14 meandering along the uneven surface including the recesses and the protrusions of the uneven group are formed on the insulating layer 7 across the second region 3B of the three-dimensional material layer 3.

The recesses 7a and the protrusions 7b extend in the Y direction and are alternately and repeatedly arranged in the X direction, but the recesses 7a and the protrusions 7b are not limited to such a configuration. It is possible to form the recesses 7a and the protrusions 7b by selectively etching a surface layer of the insulating layer 7 remote from the base 5.

Two recesses 7a are formed for each protrusion 7b, and are each shared by two protrusions 7b adjacent to each other. Then, each protrusion 7b is sandwiched between two recesses 7a. In the first embodiment, each uneven group includes three recesses 7a and two protrusions 7b. Such an uneven group is formed for each formation region of the second field-effect transistor Q2.

The two-dimensional material layer 14 is formed to continuously meander along the uneven surface including the recesses 7a and the protrusions 7b of the insulating layer 7 and with a film thickness that reflects the unevenness generated by the recesses 7a and the protrusions 7b of the insulating layer 7. Specifically, the two-dimensional material layer 14 is formed to continuously meander along the upper surface of the insulating layer 7 remote from the base 5, the inner wall surface including the bottom surface of each recess 7a, and the upper surface of each protrusion 7b and with a film thickness that reflects the unevenness generated by the recesses 7a and the protrusions 7b of the insulating layer 7.

Furthermore, the two-dimensional material layer 14 includes a two-dimensional material having a multilayer structure with a stack of two-dimensional unit layers. The two-dimensional material layer 14 can be formed by, for example, a transfer method. The two-dimensional material layer 14 preferably includes a two-dimensional material larger in band gap than the three-dimensional material layer 3. The two-dimensional material layer 14 is formed with a film thickness of, for example, about 0.3 nm to 7 nm.

In this step, the two-dimensional material layer 14 has an uneven pattern reflecting the unevenness generated by the recesses 7a and the protrusions 7b of the insulating layer 7.

Next, as illustrated in FIG. 5H, in the second region 3B of the three-dimensional material layer 3, the gate insulating film 15 and the gate electrode 16 are formed in this order on a side of the two-dimensional material layer 14 remote from the insulating layer 7.

Then, the gate insulating film 15 has an uneven pattern continuously meandering along the uneven surface including the recesses 7a and the protrusions 7b of the insulating layer 7 with the two-dimensional material layer 14 interposed therebetween to reflect the unevenness generated by the recesses 7a and the protrusions 7b of the insulating layer 7 together with the two-dimensional material layer 14.

The gate insulating film 15 is formed with a film thickness larger than the film thickness of the gate insulating film 10 of the first field transistor Q1, for example, a film thickness of about 3 nm to 8 nm.

It is possible to form the gate electrode 16 by forming the gate insulating film 15, then forming a conductive film on the entire surface of the three-dimensional material layer 3 including the inside of each recess 7a, the upper surface 6a of each protrusion 7b, and the insulating layer 7 with the gate insulating film 15 interposed therebetween, and then patterning the conductive film using a known photolithography technique and dry etching technique. As the conductive film, for example, a polycrystalline silicon (doped polysilicon) film into which impurities that reduce the resistance value are introduced during or after film formation can be used.

In this step, the gate insulating film 15 is interposed between the gate electrode 16 and the two-dimensional material layer 14.

Furthermore, in this step, the gate electrode 16 is formed into a shape having the head 16a provided on the upper surface of each protrusion 7b of the insulating layer 7 with the two-dimensional material layer 14 and the gate insulating film 15 interposed therebetween, and the leg 16b joined with the head 16a and provided in each recess 7a of the insulating layer 7 with the two-dimensional material layer 14 and the gate insulating film 15 interposed therebetween.

The head 16a is located above the upper surface of each protrusion 7b and extends over three recesses 7a and two protrusions 7b in the lateral direction (X direction) of the recesses 7a and the protrusions 7b. The leg 11b is formed in each of the three recesses 7a with the two-dimensional material layer 14 and the gate insulating film 15 interposed therebetween, and has a side opposite to the tip side connected to the head 16a.

Next, as illustrated in FIG. 5I, the pair of main electrode regions 17a and 17b each including an n-type semiconductor region are formed in the two-dimensional material layer 14 located on both sides of the gate electrode 16 in the gate length direction (Y direction). It is possible to form the pair of main electrode regions 17a and 17b by using the gate electrode 16 and the insulating layer 7 as masks for impurity introduction, implanting, for example, arsenic ions (As⁺) or phosphorus ions (P⁺) as n-type impurities into the two-dimensional material layer 14 located on both sides of the gate electrode 16 in the gate length direction (Y direction), and then subjecting the two-dimensional material layer 14 to heat treatment to activate the impurities. The pair of main electrode regions 17a and 17b are formed so as to be aligned with the gate electrode 16 and separated from each other, and function as a source region and a drain region, respectively. Each of the pair of main electrode regions 17a and 17b is formed over three recesses 7a and two protrusions 7b.

Through this step, the channel formation portion 18 is formed in the two-dimensional material layer 14 between the pair of main electrode regions 17a and 17b.

Furthermore, through this step, the second field-effect transistor Q2 including the two-dimensional material layer 14, the gate insulating film 15, the gate electrode 16, and the pair of main electrode regions 17a and 17b is formed.

Next, the multilayer wiring layer 20 including the insulating layer 21, the contact electrodes (22a, 22b, 22c, 23a, 23b, 23c), and the like is formed on a side of the insulating layer 7 remote from the three-dimensional material layer 3, resulting in the state illustrated in FIGS. 2 to 4.

### Main Effects of First Embodiment

Next, main effects of the first embodiment will be described.

As illustrated in FIG. 2, the semiconductor device 1A according to the first embodiment of the present technology includes the first thin-film field-effect transistor Q1 and the second thick-film field-effect transistor Q2 mounted on the same substrate 2. The first thin-film field-effect transistor Q1 uses each element formation portion 6 of the three-dimensional material layer 3 as the channel formation portion 13, and the second thick-film field-effect transistor Q2 uses the two-dimensional material layer 14 as the channel formation portion.

Since the two-dimensional material layer 14 is a thin monatomic layer, the two-dimensional material layer 14 is resistant to short channel effects in principle. Furthermore, since the carrier only flows in the two-dimensional direction, the mobility is higher than or equal to that of the three-dimensional material layer 3 of Si. Therefore, it is also possible for the second thick-film field-effect transistor Q2 to reduce the occupied area (footprint). In other words, for the second thick-film field-effect transistor Q2, the recesses 7a can be formed wider and deeper, so that the gate insulating film 10 can be formed in the recesses 7a to increase the gate width W, and the planar size of the second thick-film field-effect transistor Q2 can be reduced accordingly.

Furthermore, when the two-dimensional material layer 14 includes a two-dimensional material larger in band gap than the three-dimensional material layer 3, a high dielectric breakdown field strength can be obtained, and a large withstand voltage can be achieved with a thin depletion layer, so that the occupied area (footprint) of the second thin-film field-effect transistor Q2 can be further reduced.

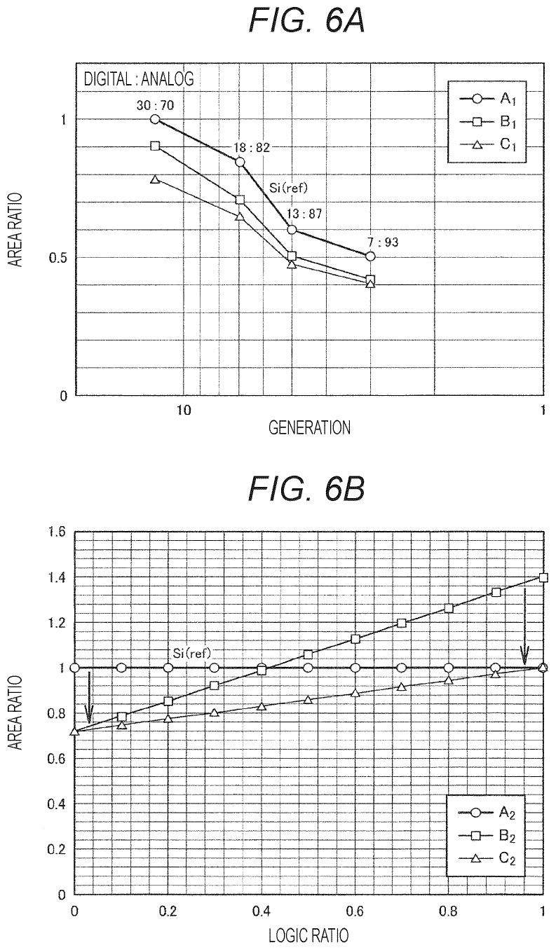

FIG. 6A is a diagram showing an area ratio of a thin-film field-effect transistor used in a digital circuit to a thick-film field-effect transistor used in an analog circuit, scaled over generations in chronological order. The thick-film type is larger in gate insulating film thickness than the thin-film type, and is also higher in drive voltage than the thin-film type.

Data A₁ in the drawing denotes data of Comparative Example 1 in a case where the channel formation portions of both the thin-film field-effect transistor and the thick-film field-effect transistor include the three-dimensional material layer of Si.

Furthermore, data B₁ in the drawing denotes data of Comparative Example 2 in a case where the channel formation portions of both the thin-film field-effect transistor and the thick-film field-effect transistor include the two-dimensional material layer that is larger in band gap than the three-dimensional material layer of Si.

Furthermore, data C₁ in the drawing denotes data of the present technology in a case where the channel formation portion of the thin-film field-effect transistor includes the three-dimensional material layer of Si, and the channel formation portion of the thick-film transistor includes the two-dimensional material layer that is larger in band gap than the three-dimensional material layer of Si.

As can be seen from FIG. 6A, the data C of the present technology has a smaller area ratio when scaled than both the data A of Comparative Example 1 and the data B of Comparative Example 2, and the area-saving effect can be maintained across generations.

FIG. 6B is a correlation diagram between an area ratio (thin-film field-effect transistor used in digital circuit: thick-film field-effect transistor used in analog circuit) and a logic ratio (logic circuit: analog circuit).

Data A₂ in the drawing denotes data of Comparative Example 3 in a case where the channel formation portions of both the thin-film field-effect transistor and the thick-film field-effect transistor include the three-dimensional material layer of Si.

Furthermore, data B₂ in the drawing denotes data of Comparative Example 4 in a case where the channel formation portions of both the thin-film field-effect transistor and the thick-film field-effect transistor include the two-dimensional material layer that is larger in band gap than the three-dimensional material layer of Si.

Furthermore, data C₂ in the drawing denotes data of the present technology in a case where the channel formation portion of the thin-film field-effect transistor includes the three-dimensional material layer of Si, and the channel formation portion of the thick-film transistor includes the two-dimensional material layer that is larger in band gap than the three-dimensional material layer of Si.

As can be seen from FIG. 6B, it is possible to achieve area saving by replacing the field-effect transistor of the analog circuit with a field-effect transistor including the two-dimensional material layer.

Therefore, with the semiconductor device 1 according to the first embodiment of the present technology, the semiconductor device 1 including the first field-effect transistor Q1 in which the channel formation portion 13 is formed in the three-dimensional material layer 3 and the second field-effect transistor Q2 in which the channel formation portion 18 is formed in the two-dimensional material layer 14 mounted on the same substrate 2, it is possible to achieve higher integration.

Furthermore, the first field-effect transistor Q1 is of a fin type in which the channel formation portion 13 is provided in the island-shaped element formation portion 6. The first fin field-effect transistor Q1 allows, when the occupied area (footprint) is the same, a large drain current to flow and an increase in transconductance gm as compared with planar field-effect transistors. It is therefore possible for the first field-effect transistor Q1 to increase the operation speed as compared with planar field-effect transistors.

The second field-effect transistor Q2 has a three-dimensional structure with an uneven pattern where the two-dimensional material layer 14 and the gate insulating film 15 continuously meander along the uneven surface including the recesses 7a and the protrusions 7b of the insulating layer 7 to reflect the unevenness generated by the recesses 7a and the protrusions 7b of the insulating layer 7. Therefore, the second field-effect transistor Q2 allows, when the occupied area (footprint) is the same, a large drain current to flow and an increase in transconductance gm as compared with planar field-effect transistors. Therefore, it is also possible for the second field-effect transistor Q2 having the three-dimensional structure to increase the operation speed as compared with planar field-effect transistors.

Here, it is necessary for the first fin field-effect transistor Q1 including the plurality of element formation portions 6 to arrange the gate insulating film 10 and the gate electrode in the valley between two element formation portions 6 adjacent to each other. Since the valley becomes narrower with miniaturization, in a case where the second thick-film field-effect transistor Q2 having a thick gate insulating film is of a fin type, miniaturization is more difficult than the first thin-film field-effect transistor Q1. When each element formation portion 6 is narrowed, the valley can be widened; however, the narrower each element formation portion 6, the stronger the electric field in the element formation portion 6, so that it is difficult to reduce the width to less than a predetermined width. Furthermore, it is possible to suppress an increase in the electric field by making the element formation portions 6 constant in width and widening the valley, but leading to an increase in the occupied area of the field-effect transistor.

Therefore, as in the first embodiment, the present technology in which the second thick-film field-effect transistor Q2 provided in the two-dimensional material layer 14 and the first thin-film field-effect transistor Q1 are mounted on the same substrate 2 is advantageous in achieving higher integration of the semiconductor device 1A.

Since the miniaturization and generational evolution of advanced MOS focus on the evolution of thin-film transistors, it is becoming increasingly difficult to simultaneously evolve other transistors such as thick-film transistors and HV transistors that are inherently difficult to scale.

In general, LSIs support multiple power supplies, and circuits with features tailored to product needs are integrated for each power supply. Thin-film transistors are mainly used at a low voltage of 1 V or less for digital processing and are required to have a high speed and a small area; on the other hand, thick-film transistors operate at a voltage above 1 V and are mainly used for analog processing or the like. Then, thick-film transistors require a large device size (occupied area) due to the need for variability suppression, electric field mitigation, and the like and desirably operate in a manner similar to traditional MOSFETs, and it is important for thick-film transistors to operate not only at I/O levels like digital but also at intermediate voltages. Moreover, high voltages above 5 V are sometimes used, such thick-film transistors are difficult to miniaturize, and when advanced CMOS Si occupies a certain proportion of the area, it can be considered an increase in cost per transistor.

Furthermore, conversely, in IoT applications, lower voltages than those used in thin-film transistors, such as 0.5 V operation, or lower leakage OFF currents are desired, and for example, new devices like tunneling FETs (TFETs) hold promise for the future; however, there are no examples of such TFETs being formed on fin portions, and in the first place, Si TFETs experience tunneling through traps in the Si, leading to high leakage, which makes them impractical.

Therefore, the present technology is advantageous in that the thin-film transistor including the three-dimensional material layer and the thick-film transistor including the two-dimensional material layer are mounted together on the same substrate.

### Second Embodiment

A semiconductor device 1B according to a second embodiment of the present technology is basically similar in configuration to the semiconductor device 1A according to the first embodiment described above, but is different mainly in configuration of the three-dimensional material layer 3.

That is, as illustrated in FIGS. 1 and 2, the three-dimensional material layer 3 of the first embodiment described above includes the base 5 provided across the first region 2A and the second region 2B of the substrate 2 (the first region 3A and the second region 3B of the three-dimensional material layer 3), and the island-shaped element formation portion 6 protruding upward from the base 5 in the first region 2A (3A). Then, in the second region 2B (3B), the two-dimensional material layer 14 of the first embodiment described above has an uneven pattern continuously meandering along the uneven surface including the recesses 7a and the protrusions 7b of the insulating layer 7 to reflect the unevenness generated by the recesses 7a and the protrusions 7b of the insulating layer 7. Then, the first field-effect transistor Q1 is provided in the element formation portions 6 of the three-dimensional material layer 3. Then, the second field-effect transistor Q2 is provided in the uneven portion of the two-dimensional material layer 14 reflecting the unevenness generated by the recesses 7a and the protrusions 7b of the insulating layer 7.

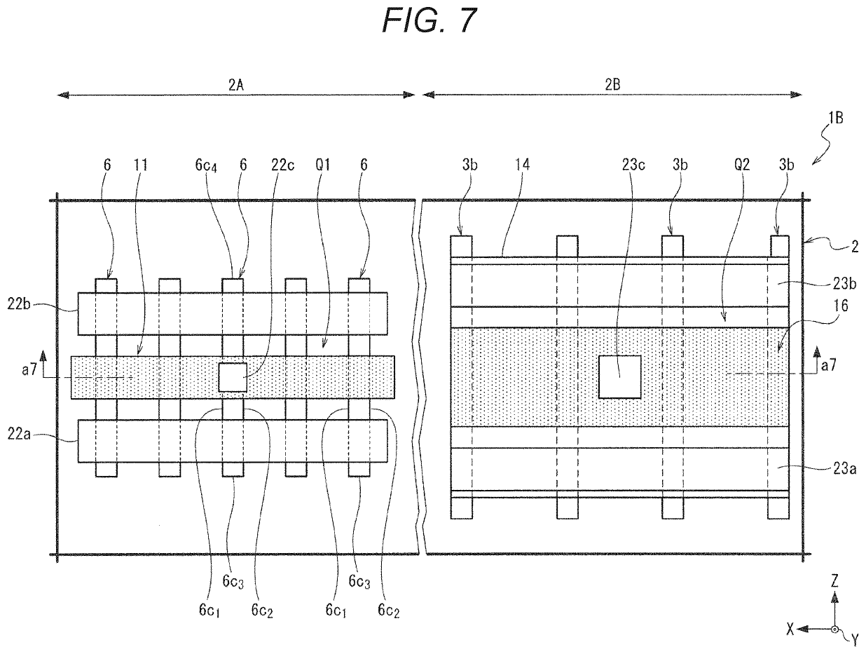

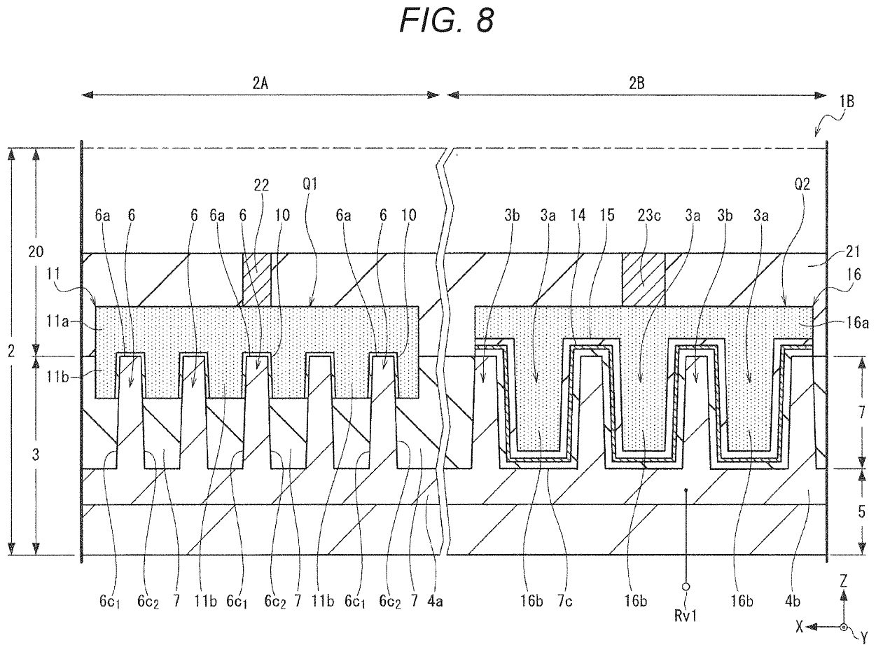

On the other hand, as illustrated in FIGS. 7 and 8, the three-dimensional material layer 3 of the second embodiment includes a base 5 and element formation portions 6, and further includes recesses 3a and protrusions 3b provided in the second region 3B. Then, in the second region 2B (3B), the two-dimensional material layer 14 of the second embodiment has an uneven pattern continuously meandering along the uneven surface including the recesses 3a and the protrusions 3b of the three-dimensional material layer 3 to reflect the unevenness generated by the recesses 3a and the protrusions 3b of the three-dimensional material layer 3. Then, the first field-effect transistor Q1 is provided in the element formation portions 6 of the three-dimensional material layer 3. Then, the second field-effect transistor Q2 is provided in the uneven portion of the two-dimensional material layer 14 reflecting the unevenness generated by the recesses 3a and the protrusions 3b of the three-dimensional material layer 3.

As illustrated in FIG. 8, the recesses 3a and the protrusions 3b of the three-dimensional material layer 3 extend in the Y direction and are alternately and repeatedly arranged in the X direction, but the recesses 3a and the protrusions 3b are not limited to such a configuration. It is possible to form the recesses 3a and the protrusions 3b by selectively etching the three-dimensional material layer 3 to such a depth that the base 5 remains. The protrusions 3b protrude upward from the base 5 and are joined with the base 5. The recesses 3a each have an inner wall surface formed by two protrusions 3b adjacent to each other and the base 5.

The recesses 3a and the protrusions 3b are provided for each second field-effect transistor Q2. The second embodiment has, but is not limited to, a configuration where an uneven group including, for example, three recesses 3a and two protrusions 3b as one unit is provided for each second field-effect transistor Q2, in a manner similar to the recesses 7a and the protrusions 7b provided in the insulating layer 7 of the first embodiment described above. FIG. 8 illustrates an example where the second field-effect transistor Q2 is provided on a one-to-one basis for each uneven group including three recesses 3a and two protrusions 3b.

As illustrated in FIG. 8, a p-type well region 4b including, for example, a p-type semiconductor region is provided in the second region 3B of the three-dimensional material layer 3. The p-type well region 4b is selectively provided in the second region 3B of the three-dimensional material layer 3 and is not provided in the first region 3A, but the p-type well region 4b is not limited to such a configuration. That is, in the second embodiment, the p-type well region 4b different from the p-type well region 4a provided in the first region 3A of the three-dimensional material layer 3 is provided in the second region 3B of the three-dimensional material layer 3.

The p-type well region 4b is provided all over the protrusions 3b in the second region 3B of the three-dimensional material layer 3, and is provided in a surface layer on a side of the base 5 adjacent to the protrusions 3b so as to be separated from a back surface of the base 5 remote from the protrusions 3b.

As illustrated in FIG. 8, a reference potential Rv1 is applied to the p-type well region 4b as a power supply potential. The second embodiment has, but is not limited to, a configuration where, for example, 0 V is applied to the p-type well region 4b as the reference potential Rv1. The reference potential Rv1 is continuously applied to the p-type well region 4b during the driving of the second field-effect transistor Q2 to fix the p-type well region 4b at the reference potential Rv1.

As illustrated in FIG. 8, an insulating layer 7c meandering along the uneven surface of the recesses 3a and the protrusions 3b of the three-dimensional material layer 3 is interposed between the three-dimensional material layer 3 and the two-dimensional material layer 14. That is, the two-dimensional material layer 14 has the uneven pattern meandering along the uneven surface including the recesses 3a and the protrusions 3b of the three-dimensional material layer 3 with the insulating layer 7c interposed therebetween to reflect the unevenness including the recesses 3a and the protrusions 3b of the three-dimensional material layer 3.

The insulating layer 7c is formed with a film thickness that reflects the unevenness including the recesses 3a and the protrusions 3b of the three-dimensional material layer 3. The insulating layer 7c also serves to electrically isolate the three-dimensional material layer 3 and the two-dimensional material layer 14, so that the insulating layer 7c is preferably formed with a film thickness of, for example, 10 nm or more. In the second embodiment, an insulating layer 7D includes, for example, a part of the insulating layer 7.

The semiconductor device 1B according to the second embodiment can also produce effects similar to those produced by the semiconductor device 1A according to the above-described first embodiment.

Furthermore, in the semiconductor device 1B according to the second embodiment, the reference potential Rv1 is applied to the p-type well region 4b to cause the protrusions 3b together with the p-type well region 4b to function as a back gate, so that the characteristics of the second field-effect transistor Q2 can be further stabilized.

Specifically, it is possible to set the threshold voltage of the second field-effect transistor Q2 by using the back gate. Furthermore, forming the structure of the protrusions 3b only in the source and drain regions (not in the channel region) makes it possible to electrically dope the source and drain regions via the back gate to reduce resistance and stabilize operation.

### Third Embodiment

A semiconductor device 1C according to a third embodiment of the present technology is basically similar in configuration to the semiconductor device 1A according to the first embodiment described above, but is different in the following configuration.

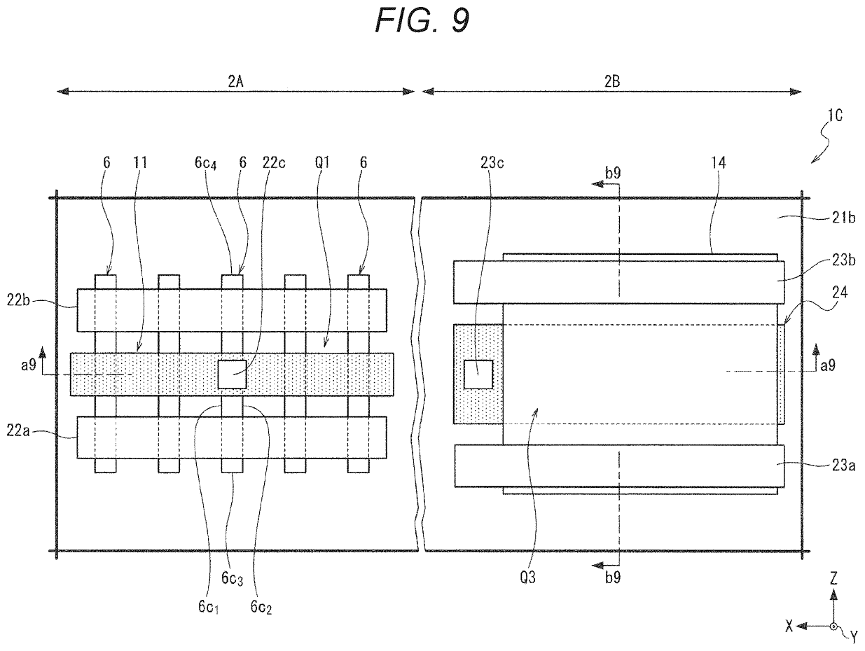

That is, as illustrated in FIGS. 9 to 11, the semiconductor device 1C according to the third embodiment includes a third field-effect transistor Q3 as the second transistor instead of the second field-effect transistor Q2 illustrated in FIGS. 1, 2, and 4 of the first embodiment described above. Then, an insulating layer 7 of the third embodiment does not include the uneven portion including the recesses 7a and the protrusions 7b illustrated in FIG. 2 of the first embodiment in the second region 3B of the three-dimensional material layer 3. Then, the semiconductor device 1C according to the third embodiment further includes an insulating layer 21a provided on a side of the insulating layer 7 remote from the three-dimensional material layer 3 so as to surround a gate electrode 24 of the third field-effect transistor Q3. The insulating layer 21a has a surface layer remote from the insulating layer 7 planarized. The other configurations are substantially similar to those of the first embodiment described above.

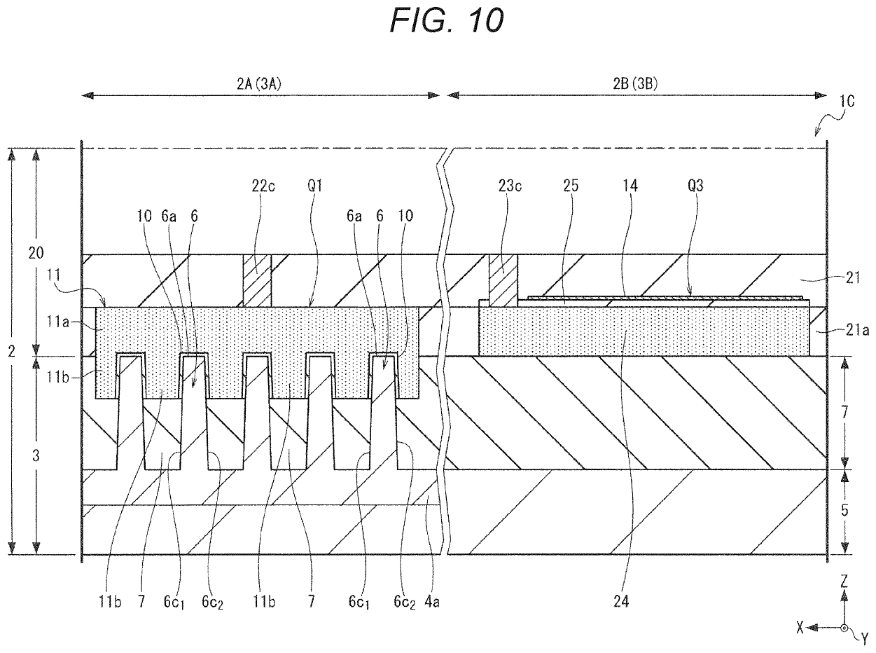

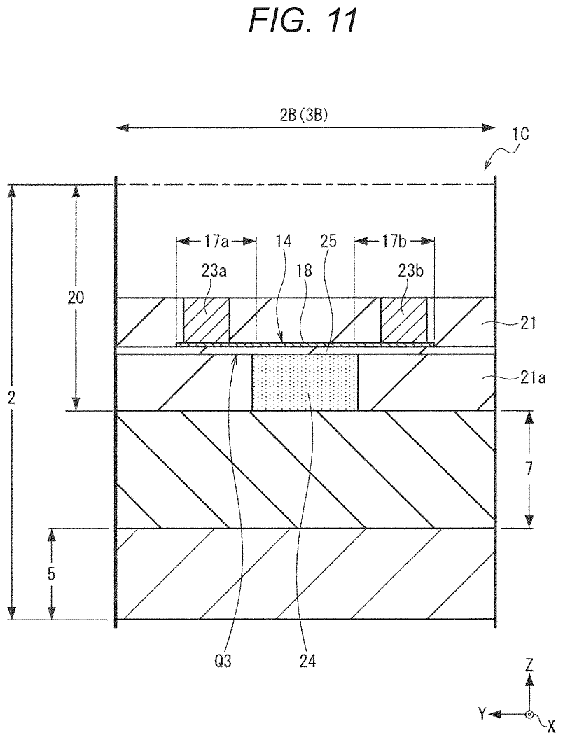

As illustrated in FIGS. 10 and 11, the two-dimensional material layer 14 and the third field-effect transistor Q3 are provided above the three-dimensional material layer 3 with the insulating layer 7 interposed therebetween in the second region 3B of the three-dimensional material layer 3.

Here, in the third embodiment, the first field-effect transistor Q1 corresponds to a specific example of the “first transistor” of the present technology, and the third field-effect transistor Q3 corresponds to a specific example of the “second transistor” of the present technology.

The third field-effect transistor Q3 illustrated in FIG. 9 is of, but not limited to, an n-channel conductivity type, for example. Then, the third field-effect transistor Q3 includes a MOSFET having a silicon oxide (SiO₂) film as a gate insulating film. The second field-effect transistor Q2 may be of a p-channel conductivity type. Alternatively, the third field-effect transistor Q3 may be a MISFET having a silicon nitride (Si₃N₄) film or a multilayer film (composite film) including a silicon nitride film and a silicon oxide film as a gate insulating film.

As illustrated in FIGS. 9 and 11, the third field-effect transistor Q3 is provided in the two-dimensional material layer 14.

As illustrated in FIGS. 10 and 11, the third field-effect transistor Q3 includes the gate electrode 24 provided on a side of the insulating layer 7 remote from the three-dimensional material layer 3, and a gate insulating film 25 provided on a side of the gate electrode 24 remote from the insulating layer 7.

Furthermore, the third field-effect transistor Q3 further includes a channel formation portion 18 provided in the two-dimensional material layer 14, and a pair of main electrode regions 17a and 17b that are provided separately from each other in the two-dimensional material layer 14 located on both sides of the gate electrode 24 in the gate length direction (Y direction) with the channel formation portion 18 interposed therebetween and function as a source region and a drain region, respectively.

The two-dimensional material layer 14 is provided above the gate electrode 24 with the gate insulating film 25 interposed therebetween. That is, unlike the first field-effect transistor Q1, the third field-effect transistor Q3 has a bottom gate structure where the gate electrode 16 is located closer to the insulating layer 7 than the pair of main electrode regions 17a and 17b and the channel formation portion 18 provided in the two-dimensional material layer 14. Furthermore, the third field-effect transistor Q3 has a stack structure where the gate electrode 24, the gate insulating film 25, and the two-dimensional material layer 14 are stacked in this order on the insulating layer 7.

The two-dimensional material layer 14 and the gate insulating film 25 are provided over, for example, the gate electrode 24 and the insulating layer 21a.

As illustrated in FIG. 10, a contact electrode 23c is electrically and mechanically connected to the gate electrode 24. As illustrated in FIG. 11, a contact electrode 23a is electrically and mechanically connected to the main electrode region 17a that is one of the pair of main electrode regions 17a and 17b, and a contact electrode 23b is electrically and mechanically connected to the other main electrode region 17b.

The third field-effect transistor Q3 is higher in drive voltage (power supply voltage (Vdd)) than the second field-effect transistor Q2 and is also higher in withstand voltage. That is, the gate insulating film 25 of the third field-effect transistor Q3 is thicker than the gate insulating film 10 of the first field-effect transistor Q1 and the gate insulating film 15 of the second field-effect transistor Q2. The gate insulating film 25 of the third field-effect transistor Q3 has a film thickness of, for example, about 10 nm to 50 nm. Then, the drive voltage (power supply voltage (Vdd)) of third field-effect transistor Q3 is, for example, about 20 V to 100 V.

The semiconductor device 1C according to the third embodiment includes the first thin-film field-effect transistor Q1 and the third thick-film field-effect transistor Q3 mounted on the same substrate 2. Therefore, the semiconductor device 1C according to the third embodiment can also achieve higher integration in a manner similar to the semiconductor device 1A according to the first embodiment described above.

Furthermore, since the third field-effect transistor Q3 has a stack structure where the gate electrode 24, the gate insulating film 25, and the two-dimensional material layer 14 are stacked in this order on the insulating layer 7, when the two-dimensional material layer 14 is formed, the two-dimensional material layer 14 can be easily formed on the gate insulating film 25 by a transfer method.

Furthermore, since the two-dimensional material layer 14 can be formed on the gate insulating film 25 by a transfer method, the film quality of the two-dimensional material layer 14 can be improved.

Note that, in the third embodiment, the case where the two levels of field-effect transistors (the first foil field-effect transistor Q1 and the third thick-film field-effect transistor Q3) having gate insulating films of different thicknesses are mounted on the same substrate 2 has been described, but the present technology can also be applied to a semiconductor device in which three levels of field-effect transistors (the first thin-film field-effect transistor Q1, the second thick-film field-effect transistor Q2, and the third thick-film field-effect transistor Q3) having gate insulating films of different thicknesses are mounted on the same substrate 2.

Furthermore, since the two-dimensional material layer 14 has a flat structure, its film formation is simple, and for example, a method in which a high-quality two-dimensional material layer 14 is formed on a different substrate and is then bonded to the substrate is also applicable. Since a film is formed on a different substrate, it is possible to prepare a high-quality film with fewer defects by means of high-temperature treatment or the like.

### Fourth Embodiment

A semiconductor device 1D according to a fourth embodiment of the present technology is basically similar in configuration to the semiconductor device 1C according to the third embodiment described above, but is different in the following configuration.

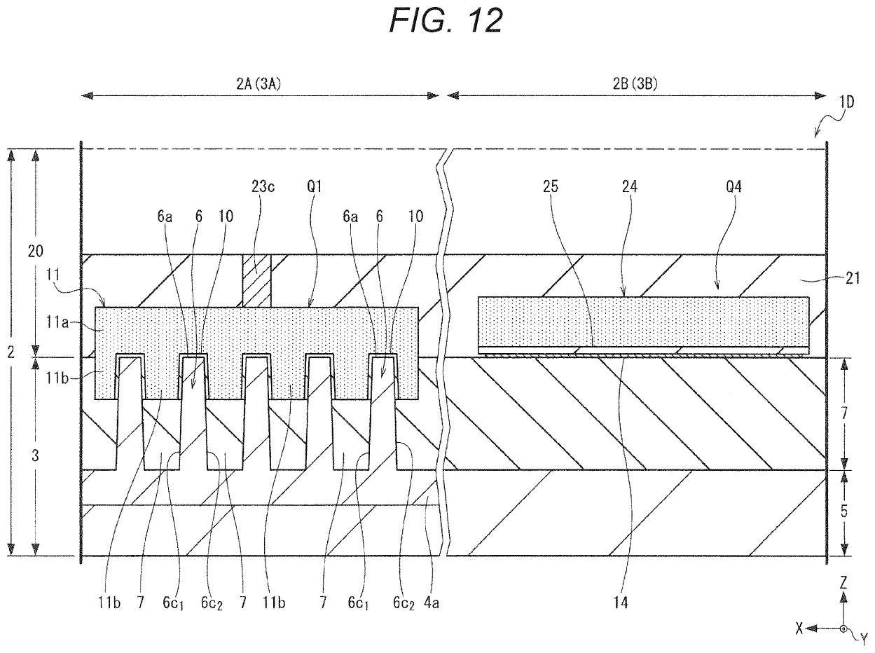

That is, as illustrated in FIG. 12, the semiconductor device 1D according to the third embodiment includes a fourth field-effect transistor Q4 as the second transistor instead of the third field-effect transistor Q3 illustrated in FIG. 10 of the third embodiment described above.

The fourth field-effect transistor Q4 of the fourth embodiment is basically similar in configuration to the field-effect transistor of the third embodiment described above, but is different in the order of the gate electrode 24, the gate insulating film 25, and the two-dimensional material layer 14.

That is, as illustrated in FIG. 12, the fourth field-effect transistor Q4 has a stack structure where the two-dimensional material layer 14, the gate insulating film 25, and the gate electrode 24 are stacked in this order on the insulating layer 4. Then, the fourth field-effect transistor Q4 is of a typical planar type. That is, the gate insulating film 25 of the fourth field-effect transistor Q4 is also thicker than the gate insulating film 10 of the first field-effect transistor Q1 in a manner similar to the third field-effect transistor Q3.

Here, in the fourth embodiment, the first field-effect transistor Q1 corresponds to a specific example of the “first transistor” of the present technology, and the fourth field-effect transistor Q4 corresponds to a specific example of the “second transistor” of the present technology.

The semiconductor device 1D according to the fourth embodiment includes the first thin-film field-effect transistor Q1 and the fourth thick-film field-effect transistor Q4 mounted on the same substrate 2. Therefore, the semiconductor device 1C according to the third embodiment can also achieve higher integration in a manner similar to the semiconductor device 1A according to the first embodiment described above.

Furthermore, in the fourth implementation, since it is only required to arrange the two-dimensional material layer 14 flat, the method in which a high-quality two-dimensional material layer 14 is bonded is also applicable, and since the gate electrode 24 is located above, a process similar to the conventional process can be used.

On the other hand, in the third embodiment described above, since the contacts for the source region and the drain region do not come next to the gate electrode 24 (since the gate electrode is located below), it can be said that parasitic capacitance is small.

### Fifth Embodiment

A semiconductor device 1E according to a fifth embodiment of the present technology is basically similar in configuration to the semiconductor device 1A according to the first embodiment described above, but is different in the following configuration.

That is, the respective gate electrodes of the first field-effect transistor Q1 and the second field-effect transistor Q2 have different shapes. The other configurations are substantially similar to those of the first embodiment described above.

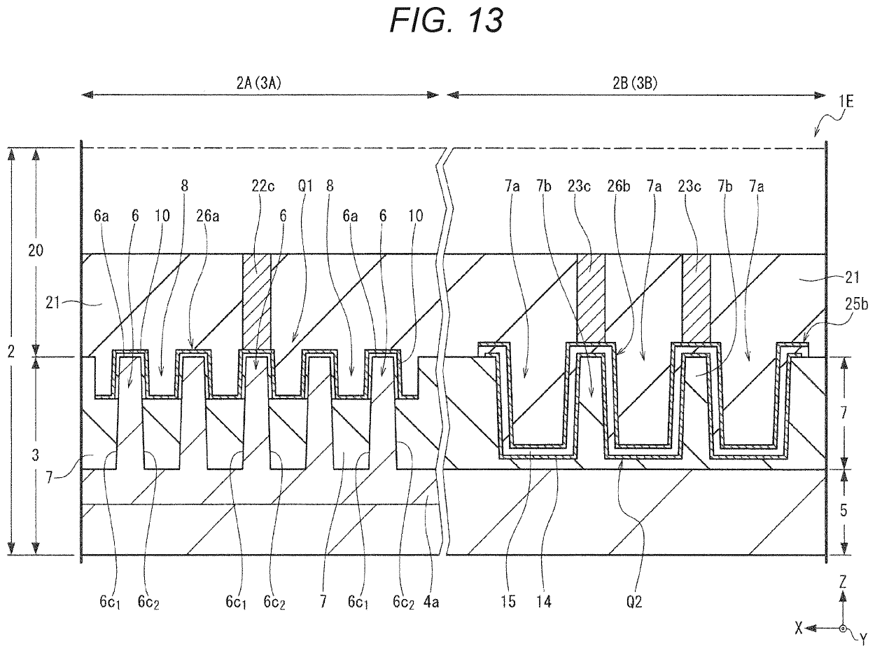

As illustrated in FIG. 13, the first field-effect transistor Q1 of the fifth embodiment includes a gate electrode 26a instead of the gate electrode 11 illustrated in FIG. 2 of the first embodiment described above. The other configurations are substantially similar to those of the first field-effect transistor Q1 of the first embodiment described above.

Furthermore, the second field-effect transistor Q2 of the fifth embodiment includes a gate electrode 26a instead of the gate electrode 16 illustrated in FIG. 2 of the first embodiment described above. The other configurations are substantially similar to those of the field-effect transistor Q2 of the second embodiment described above.

As illustrated in FIG. 13, the gate electrode 26a of the first field-effect transistor Q1 has an uneven pattern meandering along the unevenness including the recessed portions 8 and the element formation portions 6 with the gate insulating film 10 interposed therebetween to reflect the unevenness. The gate electrode 26a of the second field-effect transistor Q2 includes a two-dimensional material similar to the two-dimensional material layer 14 described above. Then, the gate electrode 26a is formed with a film thickness that reflects the unevenness including the recessed portions 8 and the element formation portions 6.

As illustrated in FIG. 13, the gate electrode 26b of the second field-effect transistor Q2 has an uneven pattern meandering along the unevenness including the recesses 7a and the protrusions 7b of the insulating layer 7 with the two-dimensional material layer 14 and the gate insulating film 15 interposed therebetween to reflect the unevenness. The gate electrode 26b of the second field-effect transistor Q2 also includes a two-dimensional material similar to the two-dimensional material layer 14 described above. Then, the gate electrode 26b is formed with a film thickness that reflects the unevenness including the recesses 7a and the protrusions 7b of the insulating layer 7.

The semiconductor device 1E according to the fifth embodiment also includes the first thin-film field-effect transistor Q1 and the second thick-film field-effect transistor Q2 mounted on the same substrate 2. Therefore, the semiconductor device 1E according to the fifth embodiment can also achieve higher integration in a manner similar to the semiconductor device 1A according to the first embodiment described above.

Furthermore, since the gate electrode 26b is thin, so that the gate electrode 24 can be formed even with the recesses 7a of the second field-effect transistor Q2 narrowed, and for example, the number of the recesses 7a in the same area can be increased, or the area can be reduced with the number of the recesses 7a constant.

### Sixth Embodiment

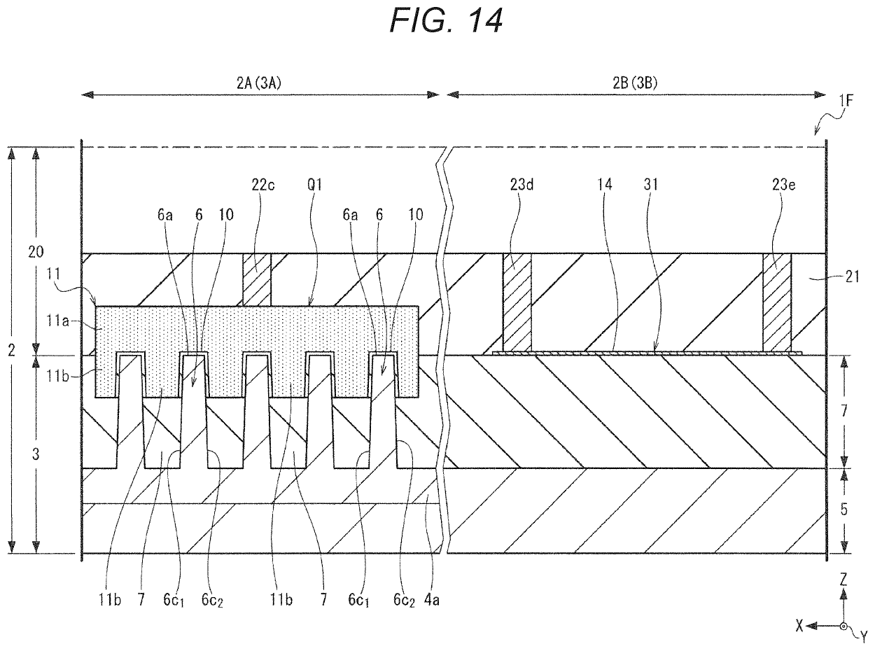

As illustrated in FIG. 14, in a semiconductor device 1F according to a sixth embodiment of the present technology, the first field-effect transistor Q1 and a resistive element 31 are mounted on the same substrate 2. Furthermore, although not illustrated in FIG. 14, in the semiconductor device 1F according to the sixth embodiment, the second field-effect transistor Q2 illustrated in FIG. 2 is also mounted on the substrate 2.

As illustrated in FIG. 14, the resistive element 31 is provided on a side of the insulating layer 7 remote from the three-dimensional material layer 3 in the second region 2B of the substrate 2 (the second region 3B of the three-dimensional material layer 3). Then, contact electrodes 23d and 23e provided in the insulating layer 21 are electrically and mechanically connected to one end and the other end of the resistive element 31, respectively. Then, the resistive element 31 includes a two-dimensional material similar to the two-dimensional material layer 14 described above. Then, the resistive element 31 is used as a circuit element constituting an analog circuit.

Here, as long as a material with a high resistance value is used as the material of the resistive element, the resistive element can be formed in a small area. By using a semiconductor region provided in the element formation region of the semiconductor layer as a resistive element (diffusion resistive element), a resistive element with a high resistance value can be obtained, but there are concerns about leakage current and affinity with advanced field-effect transistors such as a fin field-effect transistor and a GAA-structure field-effect transistor.

On the other hand, although metal is used in the multilayer wiring layer located above the semiconductor layer in which the transistors are formed, it is difficult to achieve high resistance.

Therefore, as in the sixth embodiment, the resistive element 31 includes a two-dimensional material similar to the two-dimensional material layer 14 described above, so that it is possible to set the resistance value higher even with a smaller area.

Therefore, the semiconductor device 1F according to the sixth embodiment can also achieve higher integration in a manner similar to the semiconductor device 1A according to the first embodiment described above.

In particular, for an analog circuit, a resistive element with a high resistance value is required, and a large number of resistive elements with different resistance values are used, so that the present technology is advantageous in that a resistive element used in an analog circuit and including a two-dimensional material is mounted on the same substrate together with a field-effect transistor used in a digital circuit.

### Seventh Embodiment

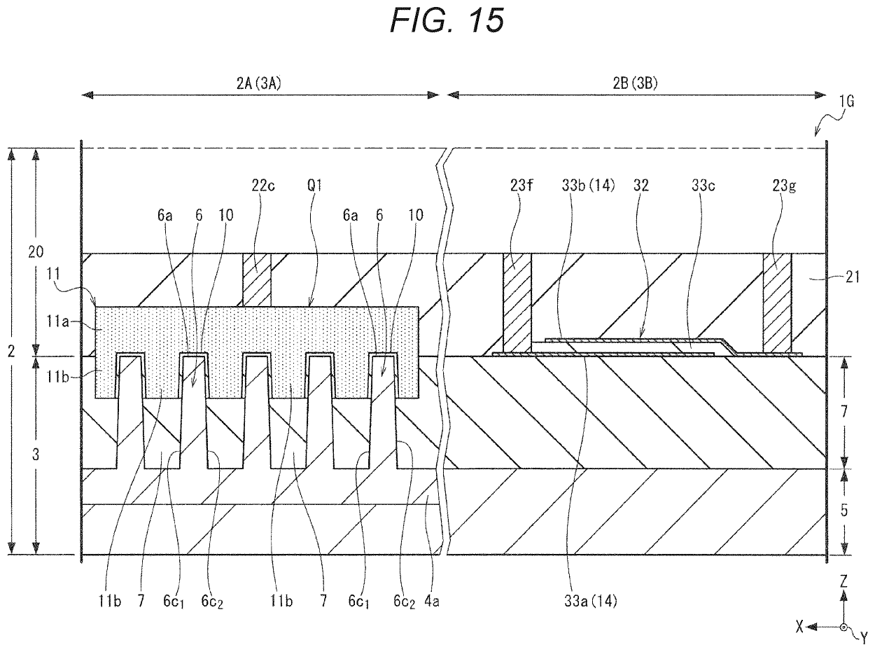

As illustrated in FIG. 15, in a semiconductor device 1G according to the sixth embodiment of the present technology, the first field-effect transistor Q1 and a capacitive element 32 are mounted on the same substrate 2. Furthermore, although not illustrated in FIG. 15, in the semiconductor device 1G according to the seventh embodiment, the second field-effect transistor Q2 illustrated in FIG. 2 is also mounted on the substrate 2.

As illustrated in FIG. 15, the capacitive element 32 is provided on a side of the insulating layer 7 remote from the three-dimensional material layer 3 in the second region 2B of the substrate 2 (the second region 3B of the three-dimensional material layer 3). Then, the capacitive element 32 has a stack structure in which a lower electrode (first electrode) 33a, a dielectric film 33c, and an upper electrode (second electrode) 33b are stacked in this order on the insulating layer 7. Then, contact electrodes 23f and 23g provided in the insulating layer 21 are electrically and mechanically connected to one end of the lower electrode 33a and one end of the upper electrode 33b, respectively. Then, at least one of the lower electrode 33a or the upper electrode 33b includes a two-dimensional material similar to the two-dimensional material layer 14 described above. Then, the capacitive element 32 is used as a circuit element constituting an analog circuit. In the seventh embodiment, both the lower electrode 33a and the upper electrode 33b include a two-dimensional material similar to the two-dimensional material layer 14 described above.

As described above, the electrodes of the capacitive element 32 include a two-dimensional material similar to the two-dimensional material layer 14 described above, so that it is possible to set the capacity larger even with a smaller area.

Furthermore, the use of a flat two-dimensional material electrode can enhance reliability as compared with the fin structure of the first field-effect transistor Q1, and the use of the most suitable electrode material for a high dielectric film allows mass formation of high-density capacitance.

Therefore, the semiconductor device 1G according to the seventh embodiment can also achieve higher integration in a manner similar to the semiconductor device 1A according to the first embodiment described above.

In particular, for an analog circuit, a large-capacity capacitive element is required, and a large number of resistive elements with different capacitance values are used, so that the present technology is advantageous in that a capacitive element used in an analog circuit and including a two-dimensional material is mounted on the same substrate together with a field-effect transistor used in a digital circuit.

### Eighth Embodiment

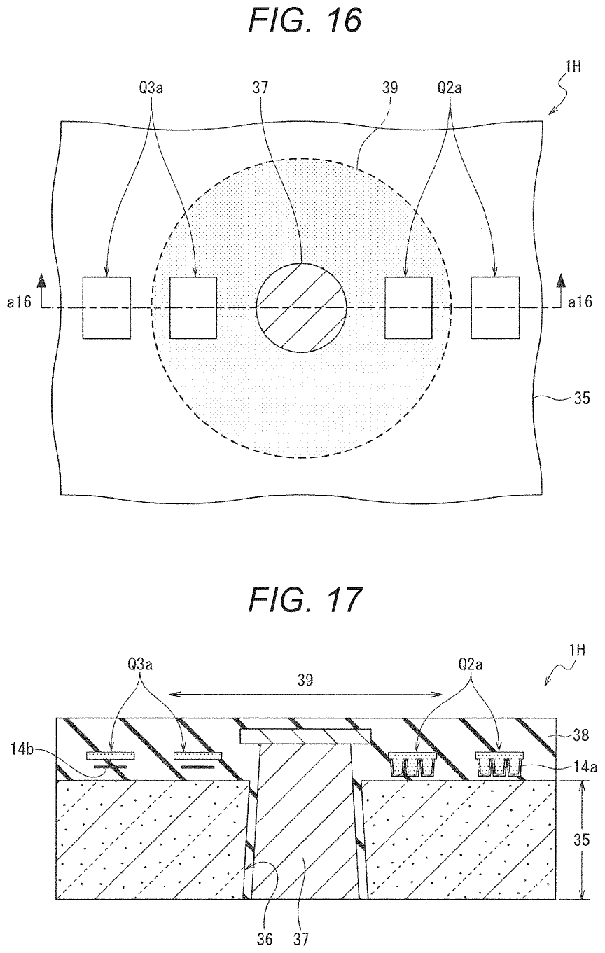

As illustrated in FIGS. 16 and 17, a semiconductor device 1H according to an eighth embodiment of the present technology includes a three-dimensional material layer 35, a through-contact electrode 37 extending through a through hole 36 of the three-dimensional material layer 35 in the thickness direction (Z direction) of the three-dimensional material layer 35, and an insulating layer 38 provided on a first surface 35a side of the three-dimensional material layer 35, the first surface 35a and a second surface 35b being located on opposite sides of the three-dimensional material layer 35 in the thickness direction.

Furthermore, the semiconductor device 1H according to the eighth embodiment includes a field-effect transistor Q2a provided together with a two-dimensional material layer 14a and a field-effect transistor Q3a provided together with a two-dimensional material layer 14b on the first surface 35a side of the three-dimensional material layer 35. The three-dimensional material layer 35 includes, for example, a material similar to the three-dimensional material layer 3 of the first embodiment described above.

The field-effect transistor Q2a is similar in configuration to the second field-effect transistor Q2 of the first embodiment described above. Furthermore, the field-effect transistor Q3a is similar in configuration to the third field-effect transistor Q3 of the third embodiment described above. Each of the field-effect transistors Q2a and Q3a is provided above the three-dimensional material layer 35 and coincides with the three-dimensional material layer 35 in plan view. Then, the field-effect transistors Q2a and Q3a are each provided in the insulating layer 38 and are arranged around the through-contact electrode 37.

The two-dimensional material layer 14a is similar in configuration to the two-dimensional material layer 14 of the first embodiment described above. Furthermore, the two-dimensional material layer 14b is similar in configuration to the two-dimensional material layer 14 of the third embodiment described above. Each of the two-dimensional material layers 14a and 14b is provided above the three-dimensional material layer 35 and coincides with the three-dimensional material layer 35 in plan view. Then, the two-dimensional material layers 14a and 14b are each provided in the insulating layer 38 and are arranged around the through-contact electrode 37.

The field-effect transistor Q2a includes the two-dimensional material layer 14a provided with a channel formation portion, in a manner similar to the second field-effect transistor Q2 of the first embodiment described above. Furthermore, the field-effect transistor Q3a includes the two-dimensional material layer 14b provided with a channel formation portion, in a manner similar to the third field-effect transistor Q3 of the third embodiment described above.

The through-contact electrode 37 extends through the through hole 36 provided in the three-dimensional material layer 35 in the thickness direction of the three-dimensional material layer 35. The insulating layer 38 is interposed between the through hole 36 of the three-dimensional material layer 35 and the through-contact electrode 37 to electrically isolate the three-dimensional material layer 35 and the through-contact electrode 37.

Here, during the manufacturing process, the through-contact electrode 37 extending through the three-dimensional material layer 35 is formed, and when returned to room temperature, stress strain occurs in the three-dimensional material layer 35 due to a difference in linear expansion coefficient between the three-dimensional material layer 35 and the through-contact electrode 37. In a case where a transistor is placed in the region where the stress strain has occurred, the characteristics of the transistor become unstable due to the piezoelectric effect, so that a keep-out zone (non-placement region) 39 is set where no transistor is allowed to be placed in the three-dimensional material layer 35 around the through-contact electrode 37.

The field-effect transistor Q2a, however, is provided in the two-dimensional material layer 14a that coincides with the three-dimensional material layer 35 in plan view.

Furthermore, the field-effect transistor Q3a is also provided in the two-dimensional material layer 14b that coincides with the three-dimensional material layer 35 in plan view. Therefore, as illustrated in FIGS. 16 and 17, the field-effect transistors Q2a and Q3a can be placed in the keep-out zone 39 of the three-dimensional material layer 35 in plan view, and the occupied area of the three-dimensional material layer 35 can be effectively used. Therefore, the semiconductor device 1H according to the eighth embodiment can achieve higher integration.

This is possible because the field-effect transistors Q2a and Q3a are not formed in the three-dimensional material layer 35, minimizing the impact of mechanical stress of the through-contact electrode 37.

In the eighth embodiment, a field-effect transistor has been described as an element to be placed in the keep-out zone 39 in plan view, but it is possible to place, not only a transistor, but also a passive element such as a resistive element, a capacitive element, or an inductor in the keep-out zone 39 in plan view.

Note that, in the first to seventh embodiments described above, the case where the first fin field-effect transistor Q1 is used as the first transistor has been described. The present technology, however, is not limited to the first fin field-effect transistor Q1. For example, the present technology can also be applied to a case where a different field-effect transistor such as a GAA-structure field-effect transistor, a nano sheet-structure field-effect transistor, or a nano frok-structure field-effect transistor is used as the first transistor.

Furthermore, the present technology can also be applied to a case where a current-driven transistor such as a bipolar transistor is used as the first transistor, for example.

The present technology can also be applied to a case where an inductor is mounted as a passive element used in an analog circuit.

### Ninth Embodiment

The present technology (technology according to the present disclosure) can be applied to a technology called Internet of things (IoT). The IoT is a mechanism in which IoT devices 9100 that are “things” are connected to another IoT device 9003, the Internet, a cloud 9005, and the like, and mutually control by exchanging information. The IoT can be utilized in various industries such as agriculture, housing, automotive, manufacturing, distribution, and energy industries.

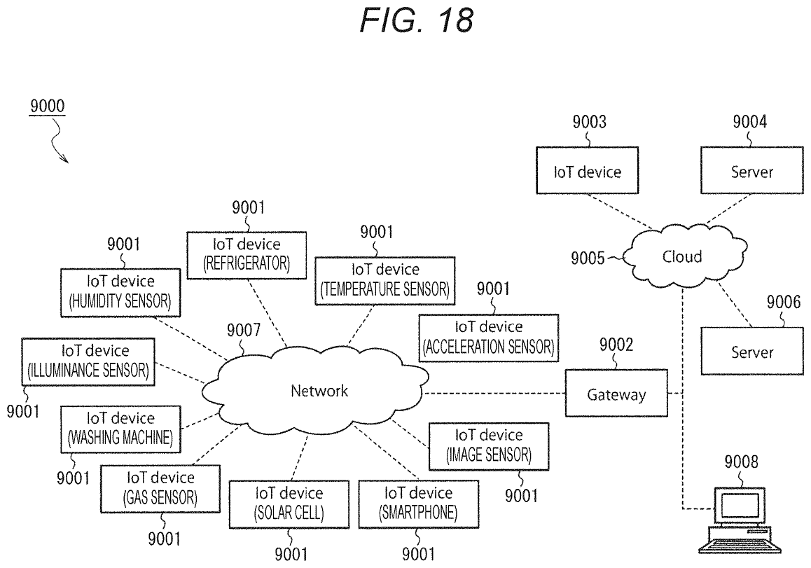

FIG. 18 is a diagram illustrating an example of a schematic configuration of an IoT system 9000 to which the present technology can be applied. The IoT devices 9001 include a variety of sensors such as temperature, humidity, illuminance, acceleration, distance, image, gas, and motion sensors. Further, the IoT devices 9001 may additionally include terminals such as a smartphone, a mobile phone, a wearable terminal, and a gaming device. The IoT devices 9001 are powered, for example, by an alternating current (AC) power supply, a direct current (DC) power supply, a battery, a non-contact power supply, energy harvesting or the like. The IoT devices 9001 can communicate by wire, wirelessly, by proximity wireless communication, or the like. As a communication method, 3G/LTE (registered trademark), Wi-Fi (registered trademark), IEEE 802.15.4, Bluetooth (registered trademark), ZigBee (registered trademark), Z-Wave, or the like is suitably used. The IoT devices 9001 may switch between the plurality of these communication means to achieve communication.

The IoT devices 9001 may form a one-to-one, star-like, tree-like, or mesh-like network. The IoT devices 9001 may connect to the external cloud 9005 directly or via a gateway 9002.

An address is assigned to each of the IoT devices 9001, for example, by internet protocol version (IPv) 4, IPv6, or over low power wireless personal area networks (6LowPAN). Data collected from the IoT devices 9001 is sent to the other IoT device 9003, a server 9004, the cloud 9005, and so on. The timings and frequency for sending data from the IoT devices 9001 may be suitably adjusted for transmission of data in a compressed form. Such data may be used in an ‘as-is’ manner or analyzed by a computer 9008 by various means such as statistical analysis, machine learning, data mining, cluster analysis, discriminant analysis, combinational analysis, and time series analysis. By utilizing such data, it is possible to provide various services such as control, warning, monitoring, visualization, automation, and optimization.

The present technology can also be applied to devices and services for home. The IoT devices 9001 in homes include washing machine, drying machine, dryer, microwave oven, dish washing machine, refrigerator, oven, electric rice cooker, cooking appliances, gas appliances, fire alarm, thermostat, air-conditioner, television (TV) set, recorder, audio appliances, lighting appliances, electric water heater, hot water dispenser, vacuum cleaner, electric fan, air purifier, security camera, lock, door-shutter opener/closer, sprinkler, toilet, thermometer, weighing scale, sphygmomanometer and the like. Moreover, the IoT devices 9001 may include a solar cell, a fuel cell, a storage battery, a gas meter, a power meter, and a distribution board.

The communication method of the IoT device 9001 at home is desirably a low-power-consumption type communication method. Furthermore, the IoT device 9001 may perform communication with Wi-Fi indoors and with 3G/LTE (registered trademark) outdoors. An external server 9006 designed to control IoT devices may be provided on the cloud 9005 to control the IoT devices 9001. The IoT devices 9001 send data including statuses of home appliances, temperature, humidity, power consumption, and presence or absence of humans and animals indoors and outdoors. Data sent from the home appliances is accumulated in the external server 9006 via the cloud 9005. New services are made available based on such data. Such an IoT device 9001 can be controlled by voice by utilizing voice recognition technology.

Furthermore, by directly sending information from various home appliances to a television, states of the various home appliances can be visualized. Further, determination of whether or not the resident is at home and transmission of data to air-conditioners and lighting appliances by various sensors makes it possible to turn the power thereof on and off. Moreover, an advertisement can be displayed on displays provided on the various home appliances, via the Internet.

Furthermore, it is preferable for such an IoT device to use a transistor suitable for low power consumption, and for example, forming a tunneling FET using a two-dimensional material as the second thick-film field-effect transistor Q2 allows the IoT device to operate at a lower voltage.

An example of the IoT system 9000 to which the present technology can be applied has been described above. The present technology can be suitably applied to a reception device for communication between various kinds of devices among the above-described configurations.

Note that the present technology can be applied not only to the applications described above, but also to various kinds of communications using a high frequency, for example. For example, the present technology can be used not only at home as described above, but also for communication in an industry such as a factory. Furthermore, for example, the present technology may be implemented in a mobile object, and mounted on a device that performs communication. The present technology is not limited to the above, and can be implemented in various kinds of applications.

Note that the present technology may have the following configurations.

(1) A semiconductor device including:
a three-dimensional material layer;
a first transistor including the three-dimensional material layer;
a two-dimensional material layer; and
a second transistor including the two-dimensional material layer, in which the first transistor and the second transistor are provided on the same substrate.
(2) The semiconductor device according to the above (1), in which
the first transistor includes a field-effect transistor including a gate electrode provided adjacent to the three-dimensional material layer with a gate insulating film interposed therebetween,
the second transistor includes a field-effect transistor including a gate electrode provided adjacent to the two-dimensional material layer with a gate insulating film interposed therebetween, and
the gate insulating film of the second transistor is thicker than the gate insulating film of the first transistor.
(3) The semiconductor device according to the above (1) or (2), in which the two-dimensional material layer is larger in band gap than the three-dimensional material layer.
(4) The semiconductor device according to the above (2) or (3), in which
the three-dimensional material layer includes a base and a plurality of element formation portions protruding from the base and arranged in parallel at predetermined intervals, and
the gate insulating film and the gate electrode of the first transistor are provided over an upper surface and a side surface of each of the plurality of element formation portions.
(5) The semiconductor device according to the above (2) or (3), in which
the two-dimensional material layer and the second transistor are provided above the three-dimensional material layer with an insulating layer interposed therebetween, and
the two-dimensional material layer and the gate insulating film of the second transistor meander along an uneven surface including recesses and protrusions provided in the insulating layer.
(6) The semiconductor device according to the above (2) or (3), in which
the two-dimensional material layer and the second transistor are provided above the three-dimensional material layer with an insulating layer interposed therebetween, and
the two-dimensional material layer and the gate insulating film of the second transistor meander along an uneven surface including recesses and protrusions provided in the three-dimensional material layer.
(7) The semiconductor device according to the above (6), in which a reference potential is applied to the protrusions of the three-dimensional material layer.
(8) The semiconductor device according to the above (6) or (7), in which the insulating layer between the three-dimensional material layer and the two-dimensional material layer has a film thickness of 10 nm or more.
(9) The semiconductor device according to the above (2), in which
the two-dimensional material layer and the second transistor are provided above the three-dimensional material layer with an insulating layer interposed therebetween, and
the two-dimensional material layer is provided above the gate electrode of the second transistor with the gate insulating film of the second transistor interposed therebetween.
(10) The semiconductor device according to any one of the above (2) to (9), in which
the two-dimensional material layer and the second transistor are provided above the three-dimensional material layer with an insulating layer interposed therebetween, and
the gate insulating film and the gate electrode of the second transistor are provided above the two-dimensional material layer.
(11) The semiconductor device according to the above (2), in which the gate electrode of each of the first and second transistors includes a two-dimensional material.
(12) The semiconductor device according to any one of the above (1) to (11), in which the three-dimensional material layer includes a material layer of any one of Si, Ge, or SiGe.
(13) The semiconductor device according to any one of the above (1) to (12), in which the two-dimensional material layer includes a two-dimensional material of any one of MoS₂, MoSe₂, MoTe₂, WS₂, WSe₂, WTe₂, ZrS₂, ZrSe₂, ZeTe₂, HfSe₂, HfTez, Graphene, or Phospherene.
(14) The semiconductor device according to any one of the above (1) to (13), further including: a digital circuit including the first transistor; and an analog circuit including the second transistor.

The scope of the present technology is not limited to the exemplary embodiments illustrated in the drawings and described above, but includes also all embodiments that produce effects equivalent to the effects that the present technology intends to produce. Moreover, the scope of the present technology is not limited to the combinations of the features of the invention defined by the claims, and may be defined by any desired combination of specific features among all the disclosed features.

### REFERENCE SIGNS LIST

1A, 1B, 1C, 1D, 1E, 1F, 1G, 1H Semiconductor device
2 Substrate
2A First region
2B Second region
3 Three-dimensional material layer
3A First region
3B Second region
4a, 4b Well region
5 Base
6 Element formation portion
6a Upper surface
6b₁, 6b₂, 6b₃, 6b₄ Side surface
7 Insulating layer
8 Recessed portion
10 Gate insulating film
11 Gate electrode
11a Head
11b Leg
12a, 12b Main electrode region
13 Channel formation portion
14, 14a, 14b Two-dimensional material layer
15 Gate insulating film
16 Gate electrode
16a Head
16b Leg
17a, 17b Main electrode region
18 Channel formation portion
20 Multilayer wiring layer
21, 21a Insulating layer
22a, 22b, 22c Contact electrode
23a, 23b, 23c, 23d, 23e, 23f, 23g Contact electrode
24 Gate electrode
25 Gate insulating film
26a, 26b Gate electrode
31 Resistive element
32 Capacitive element
33a Lower electrode
33b Upper electrode
33c Dielectric film
35 Three-dimensional material layer
35a First surface
35b Second surface
36 Through hole
37 Through-contact electrode
38 Insulating layer
39 Keep-out zone
Q1 First field-effect transistor (first transistor)
Q2 Second field-effect transistor (second transistor)
Q2a Field-effect transistor
Q3 Third field-effect transistor (second transistor)
Q3a Field-effect transistor
Q4 Fourth field-effect transistor (second transistor)
Rv1 Reference potential

What is claimed is:

1. A semiconductor device, comprising:
a three-dimensional material layer;
a first transistor including the three-dimensional material layer;
a two-dimensional material layer; and
a second transistor including the two-dimensional material layer, wherein the first transistor and the second transistor are provided on a same substrate.

2. The semiconductor device according to claim 1, wherein
the first transistor includes a field-effect transistor including a gate electrode provided adjacent to the three-dimensional material layer with a gate insulating film interposed therebetween,
the second transistor includes a field-effect transistor including a gate electrode provided adjacent to the two-dimensional material layer with a gate insulating film interposed therebetween, and
the gate insulating film of the second transistor is thicker than the gate insulating film of the first transistor.

3. The semiconductor device according to claim 1, wherein the two-dimensional material layer is larger in band gap than the three-dimensional material layer.

4. The semiconductor device according to claim 2, wherein
the three-dimensional material layer includes a base and a plurality of element formation portions protruding from the base and arranged in parallel at predetermined intervals, and
the gate insulating film and the gate electrode of the first transistor are provided over an upper surface and a side surface of each of the plurality of element formation portions.

5. The semiconductor device according to claim 2, wherein
the two-dimensional material layer and the second transistor are provided above the three-dimensional material layer with an insulating layer interposed therebetween, and
the two-dimensional material layer and the gate insulating film of the second transistor meander along an uneven surface including recesses and protrusions provided in the insulating layer.

6. The semiconductor device according to claim 2, wherein
the two-dimensional material layer and the second transistor are provided above the three-dimensional material layer with an insulating layer interposed therebetween, and
the two-dimensional material layer and the gate insulating film of the second transistor meander along an uneven surface including recesses and protrusions provided in the three-dimensional material layer.

7. The semiconductor device according to claim 6, wherein a reference potential is applied to the protrusions of the three-dimensional material layer.

8. The semiconductor device according to claim 6, wherein the insulating layer between the three-dimensional material layer and the two-dimensional material layer has a film thickness of 10 nm or more.

9. The semiconductor device according to claim 2, wherein
the two-dimensional material layer and the second transistor are provided above the three-dimensional material layer with an insulating layer interposed therebetween, and
the two-dimensional material layer is provided above the gate electrode of the second transistor with the gate insulating film of the second transistor interposed therebetween.

10. The semiconductor device according to claim 2, wherein
the two-dimensional material layer and the second transistor are provided above the three-dimensional material layer with an insulating layer interposed therebetween, and
the gate insulating film and the gate electrode of the second transistor are provided above the two-dimensional material layer.

11. The semiconductor device according to claim 2, wherein the gate electrode of each of the first and second transistors includes a two-dimensional material.

12. The semiconductor device according to claim 1, wherein the three-dimensional material layer includes a material layer of any one of Si, Ge, or SiGe.

13. The semiconductor device according to claim 1, wherein the two-dimensional material layer includes a two-dimensional material of any one of MoS₂, MoSe₂, MoTe₂, WS₂, WSe₂, WTe₂, ZrS₂, ZrSe₂, ZeTe₂, HfSe₂, HfTe₂, Graphene, or Phospherene.

14. The semiconductor device according to claim 1, further comprising: a digital circuit including the first transistor; and an analog circuit including the second transistor.
